(19) United States
(12) Patent Application Publication
(10) Pub. No.: US 2017/0329221 A1
(43) Pub. Date: Nov. 16, 2017

(54) PHOTOSENSITIVE COMPOSITION FOR FORMING RESIST UNDERLAYER FILM, AND RESIST UNDERLAYER FILM

(71) Applicant: DIC Corporation, Tokyo (JP)

(72) Inventor: Tomoyuki IMADA, Chiba (JP)

(73) Assignee: DIC Corporation, Tokyo (JP)

(21) Appl. No.: 15/532,367

(22) PCT Filed: Nov. 10, 2015
(86) PCT No.: PCT/JP2015/081572

§ 371 Date: Jun. 1, 2017

(30) Foreign Application Priority Data
Dec. 2, 2014 (JP) 2014-243948

(51) Int. Cl. G03F 7/023; C08G 8/10; G01R 33/46; C08K 5/00

(52) U.S. Cl. CPC G03F 7/0236; C08G 8/10; G01R 33/46; C08K 5/0025

(57) ABSTRACT

A photosensitive composition for the formation of resist underlayer films that contains a novolac phenolic resin resulting from an acid-catalyzed reaction between one or more phenolic trinuclear compounds (A) selected from the group consisting of the compounds of general formula (1) and the compounds of general formula (2) and an aldehyde (B).

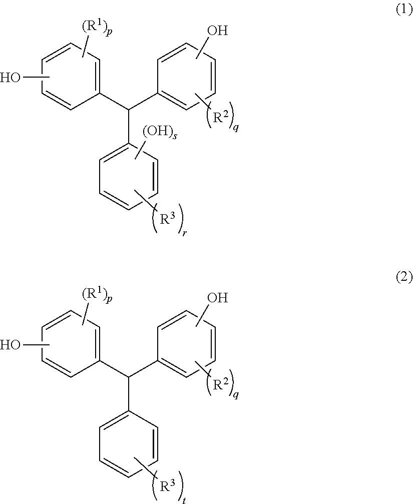

In the formulae, R¹, R², and R³ each independently represent a substituted or unsubstituted alkyl having 1 to 8 carbon atoms, R⁴ represents hydrogen, substituted or unsubstituted alkyl, or substituted or unsubstituted aryl, p and q are each independently an integer of 1 to 4, r is an integer of 0 to 4, and s is 1 or 2, with the proviso that the sum of r and s is 5 or less.

### TECHNICAL FIELD

The present invention relates to a photosensitive composition for the formation of resist underlayer films that offers superior dry etching resistance and heat resistance and easily controllable alkali solubility, and to a resist underlayer film obtained using this composition.

### BACKGROUND ART

The recent increase in the density and speed of LSI devices has created a need for finer patterning techniques. In ArF excimer laser (193 mm) photolithography, processes have been improved to overcome their intrinsic resolution limit derived from the light-source wavelength.

In the field of photoresist, a variety of processes have been developed to allow for the formation of finer wiring patterns. One of them is the multilayer resist process, in which one or more layers called resist underlayer film(s) are formed on a substrate, a resist pattern is formed on the layer(s) by an ordinary photolithographic process, and then dry etching is performed to transfer the wiring pattern to the substrate. A component important for the multilayer resist process is the resist underlayer film(s). The underlayer film(s) needs to have, for example, high resistance to dry etching, low resist-pattern line edge roughness (LER), low optical reflection, and high resistance to thermal decomposition. The resin material for the resist underlayer film(s), which is diluted in a medium prior to the formation of the film(s), needs to be soluble in commonly used organic solvents. Some modes of formation of the resist pattern require that the uncured resin composition have certain performance characteristics, such as solubility in alkaline developers and the capability of being removed during the development of the photoresist. To achieve such performance characteristics, some known compositions contain a novolac resin that has a fluorene structure and a phenolic hydroxyl group (e.g., see PTL 1).

### CITATION LIST

### Patent Literature

PTL 1: Japanese Unexamined Patent Application Publication No. 2012-252323

### SUMMARY OF INVENTION

### Technical Problem

The novolac resin that has a fluorene structure and a phenolic hydroxyl group described in PTL 1 is highly soluble in commonly used organic solvents, and cured coatings obtained using a resin composition containing this resin advantageously have low optical reflectivity. These cured coatings are, however, still unsatisfactory in terms of dry etching resistance and heat resistance.

An object of the present invention is therefore to provide a photosensitive composition for the formation of resist underlayer films that offers superior dry etching resistance and heat resistance and easily controllable alkali solubility, and a resist underlayer film made from this photosensitive composition for the formation of resist underlayer films.

### Solution to Problem

After extensive research to solve the above problem, the inventor has found, for example, that novolac phenolic resins obtained through condensation between a phenolic trinuclear compound and an aldehyde are highly resistant to dry etching and heat; and by using a phenolic trinuclear compound that has a phenolic hydroxyl group in all three benzene rings in combination with a phenolic trinuclear compound composed of two benzene rings that have a phenolic hydroxyl group and one that does not, it is possible to control the hydroxyl content of the resulting novolac phenolic resin and therefore to give the resin a desired alkali solubility. The present invention was completed on the basis of these findings.

That is, the present invention relates to a photosensitive composition for forming a resist underlayer film. The composition contains a novolac phenolic resin resulting from an acid-catalyzed reaction between one or more phenolic trinuclear compounds (A) and an aldehyde (B). The one or more phenolic trinuclear compounds are selected from the group consisting of compounds of general formula (1),

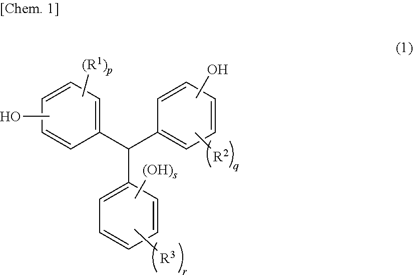

(in formula (1), R¹, R², and R³ each independently represent a substituted or unsubstituted alkyl having 1 to 8 carbon atoms; if there are a plurality of R¹ groups, the R¹ groups may be of the same or different kinds; if there are a plurality of R² groups, the R² groups may be of the same or different kinds; if there are a plurality of R³ groups, the R³ groups may be of the same or different kinds; p and q are each independently an integer of 1 to 4; r is an integer of 0 to 4; and s is 1 or 2, with the proviso that a sum of r and s is 5 or less), and

compounds of general formula (2),

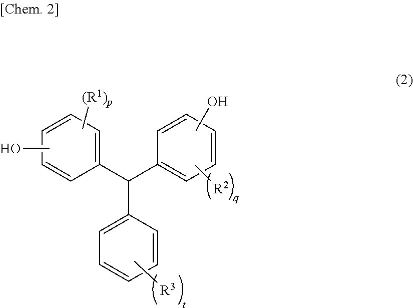

(in formula (2), R¹, R², R³, p, and q have the same meanings as in formula (1), and t is an integer of 0 to 5).

The present invention also relates to a resist underlayer film. This resist underlayer film is a cured form of the above photosensitive composition for forming a resist underlayer film.

### Advantageous Effects of Invention

Resist underlayer films obtained using the photosensitive composition according to the present invention for the formation of resist underlayer films have high dry etching resistance and heat resistance and easily controllable alkali solubility. Coatings made using the photosensitive composition according to the present invention for the formation of resist underlayer films, furthermore, have low optical reflection by virtue of the many benzene rings in the novolac phenolic resin. The photosensitive composition according to the present invention for the formation of resist underlayer films can therefore be suitably used to form anti-reflective coatings, too.

### BRIEF DESCRIPTION OF DRAWINGS

FIG. 1 is a GPC chart of phenolic trinuclear compound (1), the phenolic trinuclear compound obtained in Synthesis Example 1.

FIG. 2 is a ¹³C-NMR spectral chart of phenolic trinuclear compound (1), the phenolic trinuclear compound obtained in Synthesis Example 1.

FIG. 3 is a GPC chart of phenolic trinuclear compound (2), the phenolic trinuclear compound obtained in Synthesis Example 2.

FIG. 4 is a ¹³C-NMR spectral chart of phenolic trinuclear compound (2), the phenolic trinuclear compound obtained in Synthesis Example 2.

FIG. 5 is a GPC chart of novolac resin (3-a), the novolac resin obtained in Synthesis Example 3.

FIG. 6 is a GPC chart of novolac resin (3-b), the novolac resin obtained in Synthesis Example 4.

FIG. 7 is a GPC chart of novolac resin (3-c), the novolac resin obtained in Synthesis Example 5.

FIG. 8 is a GPC chart of novolac resin (3-d), the novolac resin obtained in Synthesis Example 6.

### DESCRIPTION OF EMBODIMENTS

A photosensitive composition according to the present invention for the formation of resist underlayer films contains a novolac phenolic resin. The novolac phenolic resin is a product of acid-catalyzed reaction between one or more phenolic trinuclear compounds (A) and an aldehyde (B). The one or more phenolic trinuclear compounds (A) are selected from the group consisting of the compounds of general formula (1) and the compounds of general formula (2). The one or more phenolic trinuclear compounds (A) as a raw material for the novolac phenolic resin (hereinafter “occasionally referred to as the novolac phenolic resin of the invention”) can be an appropriately proportioned combination of a compound of general formula (1) (a trinuclear compound that has a phenolic hydroxyl group in all three benzene rings) and a compound of general formula (2) (a phenolic trinuclear compound composed of two benzene rings that have a phenolic hydroxyl group and one that does not). By using such a raw material, it is possible to control the hydroxyl content of the resulting novolac phenolic resin, easily adjusting the alkali solubility of the resin to a desired level.

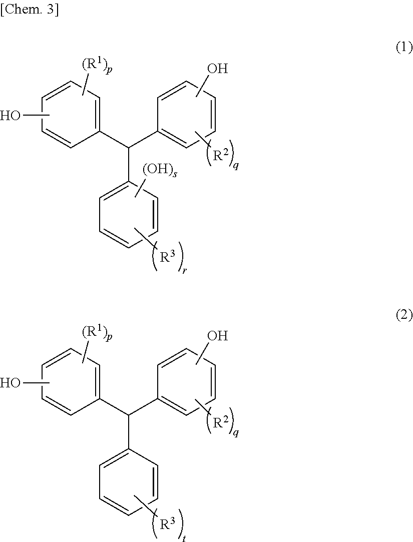

In general formulae (1) and (2), p and q are each independently an integer of 1 to 4, r is an integer of 0 to 4, and s is 1 or 2, with the proviso that the sum of r and s is 5 or less. In general formula (2), t is an integer of 0 to 5.

In general formulae (1) and (2), R¹, R², and R³ each independently represent a substituted or unsubstituted alkyl having 1 to 8 carbon atoms. If there are multiple R¹ groups, the R¹ groups may be of the same or different kinds. If there are multiple R² groups, the R² groups may be of the same or different kinds. If there are multiple R³ groups, the R³ groups may be of the same or different kinds.

The alkyl groups can be linear, branched, or cyclic, preferably linear. In the present invention, the R¹, R², and R³ alkyl groups are preferably alkyls having 1 to 6 carbon atoms, more preferably alkyls having 1 to 3 carbon atoms, even more preferably linear alkyls having 1 to 3 carbon atoms.

The R¹, R², and R³ alkyl groups in general formulae (1) and (2) may be substituted. The number of replaceable hydrogen atoms is preferably, but not limited to, between 1 and 3, more preferably 1 or 2. If one alkyl group has multiple substituents, the substituents may be of the same or different kinds.

Each of such substituents can be, for example, hydroxy, an alkoxy having 1 to 6 carbon atoms, substituted or unsubstituted aryl, or halogen. Of these substituents the alkyl groups can have, the alkoxys having 1 to 6 carbon atoms include, for example, methoxy, ethoxy, propoxy, n-butyloxy, t-butyloxy, pentyloxy, isoamyloxy, hexyolxy. The substituted or unsubstituted aryls include, for example, phenyl, naphthyl, indenyl, and biphenyl. The halogens include, for example, fluorine, chlorine, and bromine.

The R¹, R², and R³ alkyl groups in general formulae (1) and (2) can specifically be, for example, methyl, ethyl, propyl, isopropyl, n-butyl, isobutyl, t-butyl, pentyl, isoamyl, hexyl, cyclohexyl, hydroxyethyl, hydroxypropyl, fluoromethyl, methoxyethyl, ethoxyethyl, methoxypropyl, phenylmethyl, hydroxyphenylmethyl, dihydroxyphenylmethyl, tolylmethyl, xylylmethyl, naphthylmethyl, hydroxynaphthylmethyl, dihydroxynaphthylmethyl, phenylethyl, hydroxyphenylethyl, dihydroxyphenylethyl, tolylethyl, xylylethyl, naphthylethyl, hydroxynaphthylethyl, or dihydroxynapththylethyl, preferably methyl, ethyl, propyl, isopropyl, n-butyl, isobutyl, t-butyl, pentyl, isoamyl, or hexyl, more preferably methyl or ethyl, even more preferably methyl.

In general formulae (1) and (2), R¹ and R² are preferably alkyls of the same carbon number. It is preferred that R¹ and R² be bound to the same carbon atom(s), with respect to the carbon atom to which the phenolic hydroxyl group of the benzene ring is bound, in their respective benzene rings. Each of the benzene rings to which R¹ and R² are bound has a phenolic hydroxyl group bound thereto, and these phenolic hydroxyl groups preferably take the same position in their respective benzene rings. It is preferred that the numbers p and q be also equal, preferably 2.

The number r in general formulae (1) and (2) is an integer of 0 to 4. It is particularly preferred that r be 0.

The compound of general formula (1) can be, for example, a compound represented by any of general formulae (1-1) to (1-18). In general formulae (1-1) to (1-18), R¹, R², and R³ have the same meanings as in general formula (1), r1 is an integer of 0 to 4, and r2 is an integer of 0 to 3. The compounds represented by general formulae (1-1) to (1-18) are preferably ones in which both R¹ and R² are methyl or ethyl with r1 and r2 being 0, more preferably ones in which both R¹ and R² are methyl with r1 and r2 being 0.

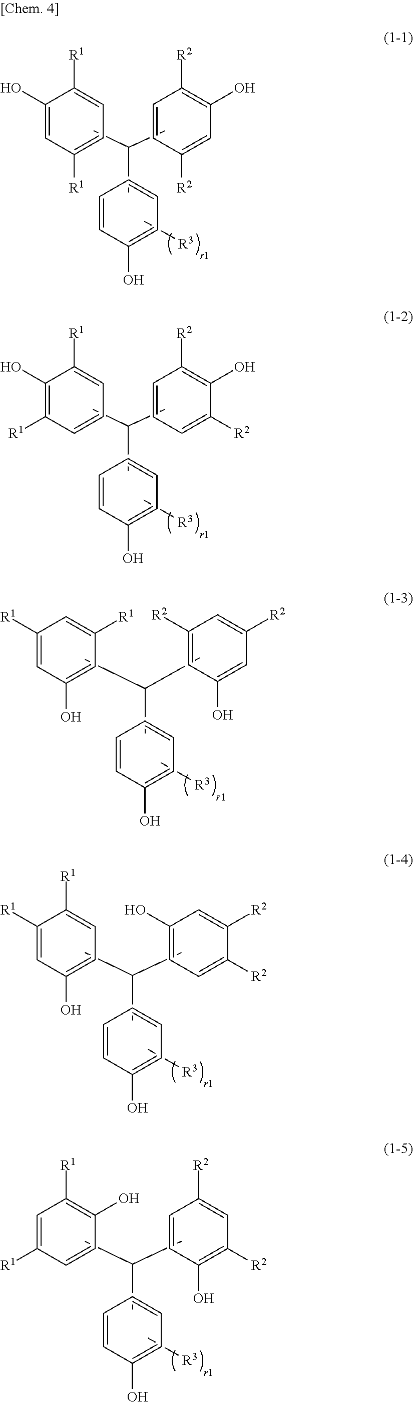

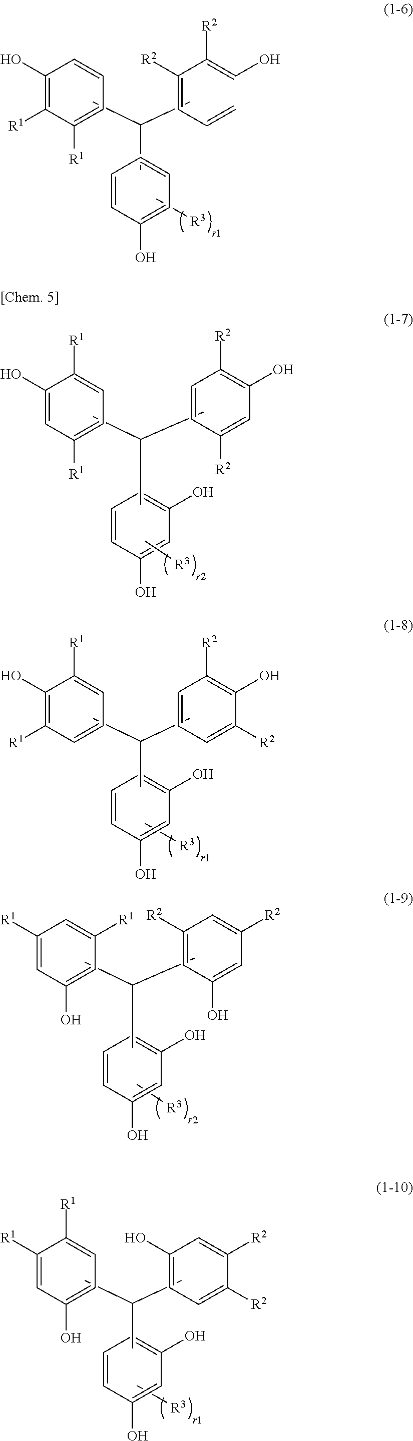

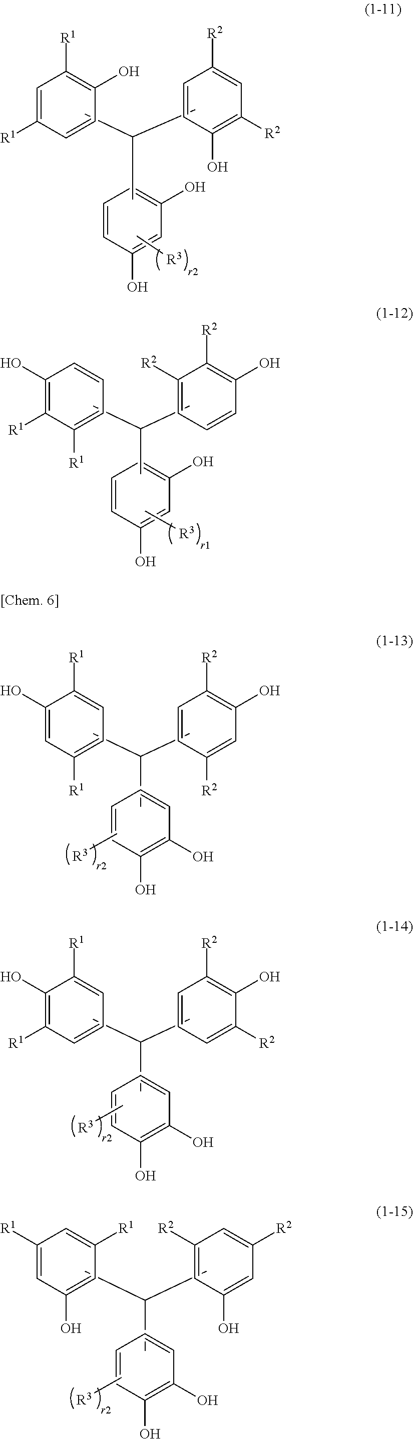

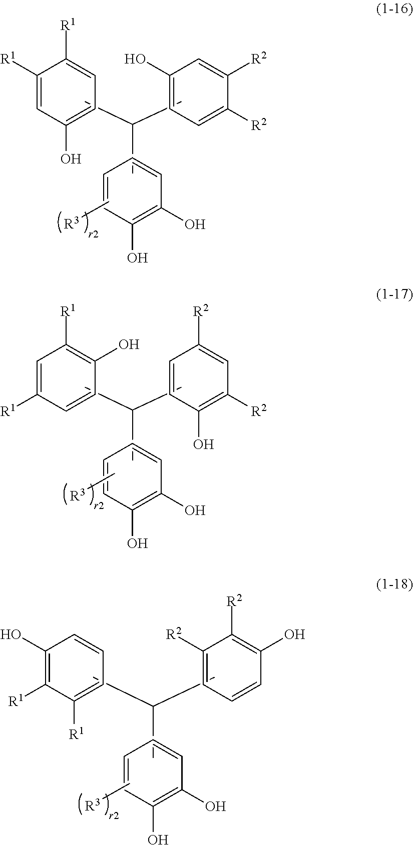

The compound of general formula (1) is preferably a compound represented by general formula (1-1), (1-2), (1-7), (1-8), (1-13), or (1-14), more preferably a compound represented by (1-1), (1-7), or (1-13), even more preferably a compound represented by general formula (1-1). With any of these compounds, coatings made using the photosensitive composition for the formation of resist underlayer films will have resistance to heat and high resolution.

The compound of general formula (2) can be, for example, a compound represented by any of general formulae (2-1) to (2-6). In general formulae (2-1) to (2-6), R¹, R², R³, and t have the same meanings as in general formula (2). The compounds represented by general formulae (2-1) to (2-6) are preferably ones in which both R¹ and R² are methyl or ethyl and t is 0, more preferably ones in which both R¹ and R² are methyl and t is 0.

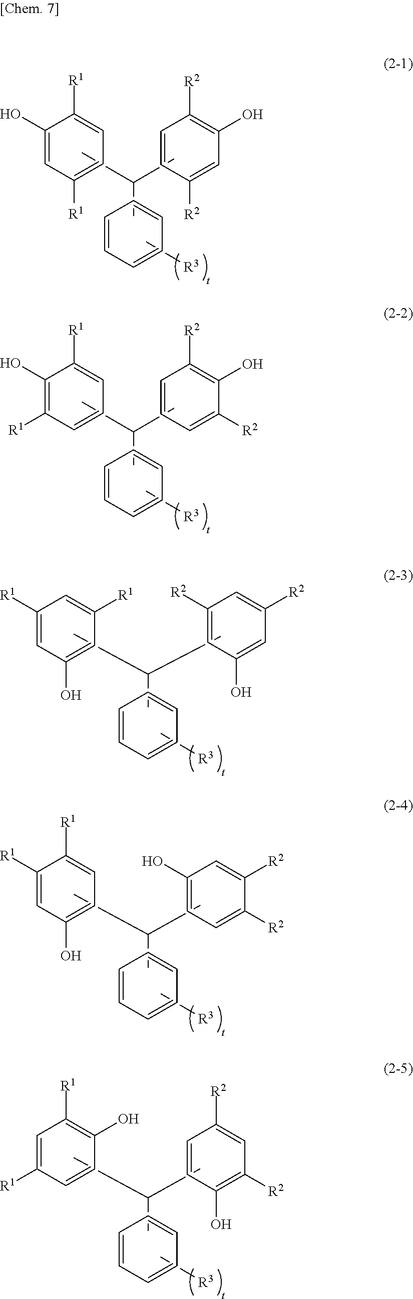

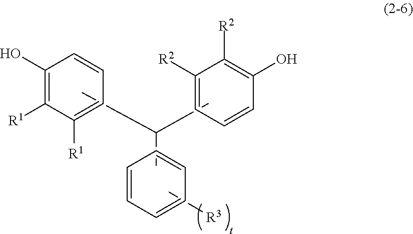

The compound of general formula (2) is preferably a compound represented by general formula (2-1) or (2-2), more preferably a compound represented by (2-1). With any of these compounds, coatings made using the photosensitive composition for the formation of resist underlayer films will have resistance to heat and high resolution.

The compound of general formula (1) can be obtained by, for example, condensing an alkyl-substituted phenol (c1) with a hydroxyl-containing aromatic aldehyde (c2) under conditions where the carbon atoms in the aromatic hydrocarbon group of the alkyl-substituted phenol (c1) have sufficiently varying reaction activity energy levels. Specifically, for example, the compound of general formula (1) can be obtained through acid-catalyzed polycondensation of an alkyl-substituted phenol (c1) and a hydroxyl-containing aromatic aldehyde (c2).

The compound of general formula (2) can be obtained by, for example, condensing an alkyl-substituted phenol (c1) with an aromatic aldehyde that has no hydroxyl group (a hydroxyl-free aromatic aldehyde) (c′2) under conditions where the carbon atoms in the aromatic hydrocarbon group of the alkyl-substituted phenol (c1) have sufficiently varying reaction activity energy levels. Specifically, for example, the compound of general formula (1) can be obtained through acid-catalyzed polycondensation of an alkyl-substituted phenol (c1) and a hydroxyl-free aromatic aldehyde (c′2).

The alkyl-substituted phenol (c1) is a phenol the benzene ring of which has been partially or completely substituted with alkyl. The alkyl can be, for example, an alkyl having 1 to 8 carbon atoms, preferably methyl in particular. Examples of alkyl-substituted phenols (c1) include monoalkylphenols such as o-cresol, m-cresol, p-cresol, o-ethylphenol, m-ethylphenol, p-ethylphenol, p-octylphenol, p-t-butylphenol, o-cyclohexylphenol, m-cyclohexylphenol, and p-cyclohexyl phenol; dialkylphenols such as 2,5-xylenol, 3,5-xylenol, 3,4-xylenol, 2,4-xylenol, and 2,6-xylenol; and trialkylphenols such as 2,3,5-trimethylphenol and 2,3,6-tr methylphenol. Of these alkyl-substituted phenols, phenols whose benzene ring has been substituted with two alkyl groups are particularly preferred because of a good balance between heat resistance and alkali solubility. To take some specific examples, 2,5-xylenol and 2,6-xylenol are preferred. Either one alkyl-substituted phenol (c1) or a combination of two or more alkyl-substituted phenols (c1) can be used. However, it is preferred to use one alkyl-substituted phenol (c1).

The hydroxyl-containing aromatic aldehyde (c2) is a compound that has an aromatic ring and at least one aldehyde group and at least one hydroxyl group in the aromatic ring. Examples of hydroxyl-containing aromatic aldehydes (c2) include hydroxybenzaldehydes such as salicylaldehyde, m-hydroxybenzaldehyde, and p-hydroxybenzaldehyde; dihydroxybenzaldehydes such as 2,4-dihydroxybenzaldehyde and 3,4-dihydroxybenzaldehyde; and vanillin compounds such as vanillin, ortho-vanillin, isovanillin, and ethyl vanillin. Of these hydroxyl-containing aromatic aldehydes (c2), p-hydroxybenzaldehyde (4-hydroxybenzaldehyde), 2,4-dihydroxybenzaldehyde, and 3,4-dihydroxybenzaldehyde are particularly preferred because of industrial availability and a good balance between heat resistance and alkali solubility. p-Hydroxybenzaldehyde is more preferred than the others.

The hydroxyl-free aromatic aldehyde (c′2) is a compound that has an aromatic ring and at least one aldehyde group and no phenolic hydroxyl group in the aromatic ring. Examples of hydroxyl-free aromatic aldehydes (c′2) include benzaldehyde; alkylbenzaldehydes such as methylbenzaldehyde, ethylbenzaldehyde, dimethylbenzaldehyde, and diethylbenzaldehyde; and alkoxybenzaldehydes such as methoxybenzaldehyde and ethoxybenzaldehyde. Of these hydroxyl-free aromatic aldehydes (c′2), benzaldehyde is particularly preferred.

The compound of general formula (1) or (2) can be obtained through, for example, acid-catalyzed polycondensation between an alkyl-substituted phenol (c1) and a hydroxyl-containing aromatic aldehyde (c2) or hydroxyl-free aromatic aldehyde (c′2). For example, acid-catalyzed polycondensation of 2,5-xylenol and 4-hydroxybenzaldehyde gives a compound of general formula (1-1) in which both R¹ and R² are methyl and r is 0. Acid-catalyzed polycondensation of 2,6-xylenol and 4-hydroxybenzaldehyde gives a compound of general formula (1-2) in which both R¹ and R² are methyl and r is 0.

The acid catalyst can be, for example, acetic acid, oxalic acid, sulfuric acid, hydrochloric acid, phenolsulfonic acid, para-toluenesulfonic acid, zinc acetate, or manganese acetate. Either one acid catalyst or a combination of two or more acid catalysts can be used. Of these acid catalysts, sulfuric acid and para-toluenesulfonic acid are particularly preferred because of their superior activity. The acid catalyst can be added before the reaction or during the reaction.

An organic solvent may optionally be included in the system for the polycondensation between an alkyl-substituted phenol (c1) and a hydroxyl-containing aromatic aldehyde (c2) or hydroxyl-free aromatic aldehyde (c′2). Examples of organic solvents that can be used include monoalcohols such as methanol, ethanol, and propanol; polyols such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, and glycerol; glycol ethers such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, and ethylene glycol monophenyl ether; cyclic ethers such as 1,3-dioxane and 1,4-dioxane; glycol esters such as ethylene glycol acetate; and ketones such as acetone, methyl ethyl ketone, and methyl isobutyl ketone. Either one organic solvent or a combination of two or more organic solvents can be used. Of these organic solvents, 2-ethoxyethanol, in which the resulting compound is highly soluble, is particularly preferred.

The reaction temperature for the polycondensation between the alkyl-substituted phenol (c1) and the hydroxyl-containing aromatic aldehyde (c2) or hydroxyl-free aromatic aldehyde (c′2) is, for example, between 60° C. and 140° C. The reaction time is, for example, between 0.5 and 100 hours.

The charge-in ratio between the alkyl-substituted phenol (c1) and hydroxyl-containing aromatic aldehyde (c2) [(c1)/(c2)] and that between the alkyl-substituted phenol (c1) and hydroxyl-free aromatic aldehyde (c′2) [(c1)/(c′2)] each preferably fall within the range of 1/0.2 to 1/0.5, more preferably 1/0.25 to 1/0.45, by molar ratio. Reactions performed in these ranges are advantageous in terms of the removal of unreacted alkyl-substituted phenol (c1), product yield, and purity of the reaction product.

In the reaction solution for the polycondensation between the alkyl-substituted phenol (c1) and the hydroxyl-containing aromatic aldehyde (c2) and hydroxyl-free aromatic aldehyde (c′2), there may remain unreacted material together with the polycondensation product, the compound of general formula (1) or (2). Unwanted condensation products, furthermore, may have been formed besides the compound of general formula (1) or (2). Thus, it is preferred to purify the compound of general formula (1) or (2) from the reaction solution that has gone through the polycondensation before using it as a raw material (a phenolic trinuclear compound (A)) for the novolac phenolic resin of the invention. It is preferred that the compound of general formula (1) or (2) to be used as a phenolic trinuclear compound (A) have a purity of 85% or more, more preferably 90% or more, even more preferably 94% or more, in particular 98% or more. The purity of the compound of general formula (1) or (2) can be determined from a ratio of areas in a GPC chart.

In an exemplary method for purifying the compound of general formula (1) or (2), the reaction solution that has gone through the polycondensation is put into a poor solvent (S1), in which the compound of general formula (1) or (2) is insoluble or sparingly soluble, the resulting precipitation is collected through filtration, the collected precipitation is dissolved in a solvent (S2) that dissolves the compound of general formula (1) or (2) and is compatible with the poor solvent (S1), the resulting solution is put into the poor solvent (S1), and the resulting precipitation is collected through filtration. Examples of poor solvents (S1) that can be used include water; monoalcohols such as methanol, ethanol, and propanol; aliphatic hydrocarbons such as n-hexane, n-heptane, n-octane, and cyclohexane; and aromatic hydrocarbons such as toluene and xylene. Of these poor solvents (S1), water and methanol are particularly preferred because they are efficient solvents that also remove the acid catalyst. Examples of solvents (S2) include monoalcohols such as methanol, ethanol, and propanol; polyols such as ethylene glycol, 1,2-propanediol, 1,3-propanediol, 1,4-butanediol, 1,5-pentanediol, 1,6-hexanediol, 1,7-heptanediol, 1,8-octanediol, 1,9-nonanediol, trimethylene glycol, diethylene glycol, polyethylene glycol, and glycerol; glycol ethers such as 2-ethoxyethanol, ethylene glycol monomethyl ether, ethylene glycol monoethyl ether, ethylene glycol monopropyl ether, ethylene glycol monobutyl ether, ethylene glycol monopentyl ether, ethylene glycol dimethyl ether, ethylene glycol ethyl methyl ether, and ethylene glycol monophenyl ether; cyclic ethers such as 1,3-dioxane and 1,4-dioxane; glycol esters such as ethylene glycol acetate; and ketones such as acetone, methyl ethyl ketone, and methyl isobutyl ketone. When the poor solvent (S1) is water, it is preferred that the (S2) be acetone. Either one poor solvent (S1) or a combination of two or more poor solvents (S1) can be used, and either one solvent (S2) or a combination of two or more solvents (S2) can be used.

The one or more phenolic trinuclear compounds (A), a raw material for the novolac phenolic resin of the invention, can be one or two or more compounds of general formula (1), one or two or more compounds of general formula (2), or a combination of one or two or more compounds of general formula (1) and one or two or more compounds of general formula (2). By adjusting the proportions of compounds of general formula (1) and compounds of general formula (2) in phenolic trinuclear compounds (A), it is possible to adjust the hydroxyl content of the resulting novolac phenolic resin. For example, a higher proportion of compounds of general formula (1) in phenolic trinuclear compounds (A) leads to a higher hydroxyl content and higher alkali solubility of the novolac phenolic resin, whereas a higher proportion of compounds of general formula (2) in phenolic trinuclear compounds (A) leads to a lower hydroxyl content and lower alkali solubility of the novolac phenolic resin.

The aldehyde (B), a raw material for the novolac phenolic resin of the invention, can be, for example, a compound of general formula (3). In general formula (3), R⁴ represents hydrogen, substituted or unsubstituted alkyl, or substituted or unsubstituted aryl. It is also possible to use a combination of two or more compounds as raw material aldehydes (B).

[Chem. 8]

R⁴—CHO (3)

Of the compounds represented by general formula (3), particularly preferred are, for example, formaldehyde; alkylaldehydes such as acetaldehyde, propylaldehyde, butylaldehyde, isobutylaldehyde, pentylaldehyde, and hexylaldehyde; hydroxybenzaldehydes such as salicylaldehyde, 3-hydroxybenzaldehyde, 4-hydroxybenzaldehyde, 2-hydroxy-4-methylbenzaldehyde, 2,4-dihydroxybenzaldehyde, and 3,4-dihydroxybenzaldehyde; alkoxybenzaldehydes that have both hydroxy and alkoxy groups such as 2-hydroxy-3-methoxybenzaldehyde, 3-hydroxy-4-methoxybenzaldehyde, 4-hydroxy-3-methoxybenzaldehyde, 3-ethoxy-4-hydroxybenzaldehyde, and 4-hydroxy-3,5-dimethoxybenzaldehyde; alkoxybenzaldehydes such as methoxybenzaldehyde and ethoxybenzaldehyde; hydroxynaphthaldehydes such as 1-hydroxy-2-naphthaldehyde, 2-hydroxy-1-naphthaldehyde, and 6-hydroxy-2-naphthaldehyde; and halogenated benzaldehydes such as bromobenzaldehyde. Formaldehyde and alkylaldehydes are more preferred. Even more preferred are formaldehyde, acetaldehyde, propylaldehyde, butylaldehyde, isobutylaldehyde, pentylaldehyde, and hexylaldehyde, in particular formaldehyde. Formaldehyde as an aldehyde (B) may optionally be used with other aldehydes. It is preferred that 0.05 to 1 mole of optional aldehyde(s), if used with formaldehyde, be used per mole of formaldehyde.

The novolac phenolic resin of the invention is obtained through, for example, acid-catalyzed condensation of a phenolic trinuclear compound (A) and an aldehyde (B). The charge-in ratio between the phenolic trinuclear compound (A) and aldehyde (B) [(A)/(B)] is preferably in the range of 1/0.5 to 1/1.2, more preferably 1/0.6 to 1/0.9, by molar ratio. Reactions performed in these ranges are free from excessive polymerization (gelling), giving the phenolic resin a molecular weight appropriate for the formation of resist underlayer films.

Examples of acid catalysts for the reaction include inorganic acids such as sulfuric acid, hydrochloric acid, nitric acid, hydrobromic acid, perchloric acid, and phosphoric acid, sulfonic acids such as p-toluenesulfonic acid, methanesulfonic acid, and benzenesulfonic acid, organic acids such as oxalic acid, succinic acid, malonic acid, monochrome acetic acid, and dichloroacetic acid, and Lewis acids such as boron trifluoride, anhydrous aluminum chloride, and zinc chloride. Of these, sulfuric acid and p-toluenesulfonic acid are particularly preferred because they actively promote the reaction between the phenolic trinuclear compound (A) and aldehyde (B) with their strong acidity. It is preferred that 0.1% to 25% by mass acid catalyst(s) be used with respect to the total mass of the reactants.

An organic solvent may optionally be included in the system for the condensation between the phenolic trinuclear compound (A) and aldehyde (B). Examples of organic solvents that can be used are the same as those of organic solvents that can be used in the aforementioned polycondensation between an alkyl-substituted phenol (c1) and a hydroxyl-containing aromatic aldehyde (c2). Either one organic solvent or a combination of two or more organic solvents can be used. 2-Ethoxyethanol, in which the resulting novolac phenolic resin is highly soluble, is preferred.

The novolac phenolic resin of the invention preferably has, for example, one or more structural portions, as a repeat unit or units, selected from the group consisting of structural units (I-1) of general formula (I-1), structural units (I-2) of general formula (I-2), structural units (II-1) of general formula (II-1), and structural units (II-2) of general formula (II-2). In general formulae (I-1), (I-2), (II-1), and (II-2), R¹ and R² have the same meanings as in general formula (1), and R⁴ has the same meaning as in general formula (3). The structural units represented by general formula (I-1), (I-2), (II-1), or (II-2) are preferably ones in which R¹ and R² are groups of the same kind with R⁴ being hydrogen, more preferably ones in which R¹ and R² are alkyl groups of the same kind that are unsubstituted and have 1 to 3 carbon atoms with R⁴ being hydrogen, even more preferably ones in which both R¹ and R² are both methyl R⁴ being hydrogen.

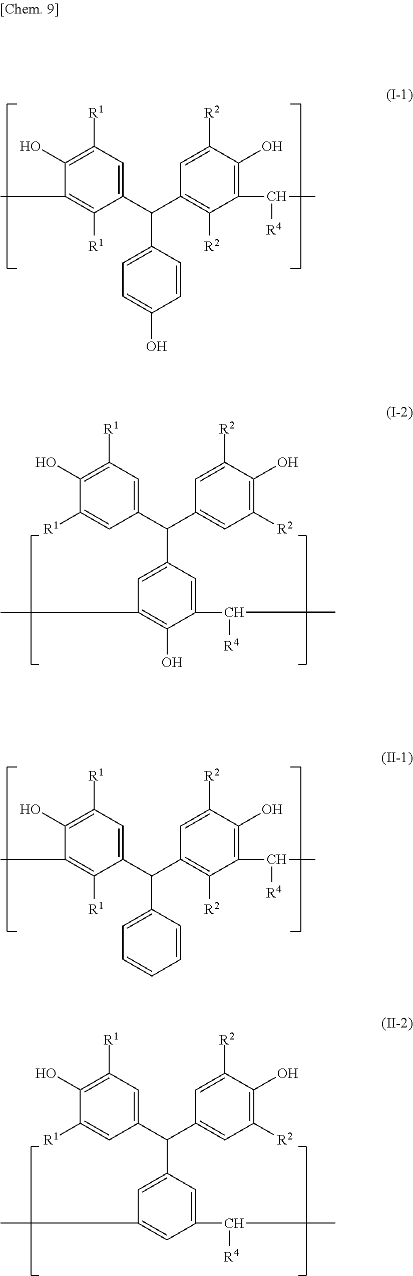

The novolac phenolic resin of the invention preferably has a weight-average molecular weight of 1,000 to 100,000, more preferably 1,000 to 70,000, even more preferably 1,000 to 35,000. In particular, novolac phenolic resins that have a structural unit of general formula (I-1) or a structural unit of general formula (II-1) as a repeat unit preferably have a weight-average molecular weight (Mw) of 5,000 to 100,000, more preferably 5,000 to 70,000, even more preferably 5,000 to 35,000, in particular 7,000 to 25,000. This gives the resulting photosensitive composition for the formation of resist underlayer films superior dry etching resistance and heat resistance.

Novolac phenolic resins that have a structural unit of general formula (I-2) or a structural unit of general formula (II-2) as a repeat unit preferably have a weight-average molecular weight (Mw) of 1,000 to 5,000, more preferably 2,000 to 4,000. This gives the resulting photosensitive composition for the formation of resist underlayer films superior dry etching resistance and heat resistance.

In the present invention and specification, the weight-average molecular weight (Mw) and number-average molecular weight (Mn) of a novolac phenolic resin are values measured using gel permeation chromatography (hereinafter abbreviated to “GPC”) under the following conditions.

### [GPC Conditions]

Instrument: Tosoh Corporation “HLC-8220 GPC”

Columns: Showa Denko K.K. “Shodex KF802” (8.0 mm I.D.×300 mm)+Showa Denko K.K. “Shodex KF802” (8.0 mm I.D.×300 mm)+Showa Denko K.K. “Shodex KF803” (8.0 mm I.D.×300 mm)+Showa Denko K.K. “Shodex KF804” (8.0 mm I.D.×300 mm)

Column temperature: 40° C.

Detector: RI (a differential refractometer)

Data processing: Tosoh Corporation “GPC-8020 Model II Version 4.30”

Developing solvent: Tetrahydrofuran

Flow rate: 1.0 mL/min

Sample: A solution of 0.5% by mass resin, on a solid basis, in tetrahydrofuran filtered through a microfilter

Injection volume: 0.1 mL

Standard samples: The below listed monodisperse polystyrenes

### (Standard Samples: Monodisperse Polystyrenes)

Tosoh Corporation “A-500”

Tosoh Corporation “A-2500”

Tosoh Corporation “A-5000”

Tosoh Corporation “F-1”

Tosoh Corporation “F-2”

Tosoh Corporation “F-4”

Tosoh Corporation “F-10”

Tosoh Corporation “F-20”

By virtue of the many benzene rings in the novolac phenolic resin of the invention, a photosensitive composition for the formation of resist underlayer films that contains this novolac phenolic resin provides coatings with superior dry etching resistance and heat resistance. Resist material coatings made from the photosensitive composition according to the present invention for the formation of resist underlayer films are therefore suitable for use as underlayer films.

Furthermore, coatings made from the photosensitive composition for the formation of resist underlayer films have low optical reflection because the benzene rings derived from the novolac phenolic resin absorb light. Coatings made from the photosensitive composition according to the present invention for the formation of resist underlayer films are therefore suitable for use as anti-reflective coatings, too.

The photosensitive composition according to the present invention for the formation of resist underlayer films may contain, besides the novolac phenolic resin of the invention, other alkali-soluble resins. Any alkali-soluble resin can be used that is soluble in alkali developers by itself or dissolves in alkali developers when used in combination with additives such as a photo-acid generator.

Examples of optional alkali-soluble resins that can be used include phenolic-hydroxyl-containing resins other than the novolac phenolic resin of the invention, homopolymers and copolymers of p-hydroxystyrene, p-(1,1,1,3,3,3-hexafluoro-2-hydroxypropyl)styrene or other hydroxy-containing styrenes, their derivatives resulting from altering their hydroxyl groups with carbonyl, benzyloxycarbonyl, or other acid-decomposing groups, homopolymers and copolymers of (meth)acrylic acid, and alternating copolymers of alicyclic polymerizable monomers, such as norbornene compounds and tetracyclodecene compounds, with maleic anhydride or maleimide.

Examples of phenolic-hydroxyl-containing resins other than the novolac phenolic resin of the invention include phenolic resins such as phenol novolac resins, cresol novolac resins, naphthol novolac resins, co-condensed novolac resins made from several phenolic compounds, phenolic resins modified with aromatic hydrocarbon formaldehyde resins, resins of dicyclopentadiene phenol adduct type, phenol aralkyl resins (Xylok resins), naphthol aralkyl resins, trimethylolmethane resins, tetraphenylolethane resins, biphenyl-modified phenolic resins (polynuclear phenolic compounds in which bis-methylene group(s) connects phenolic nuclei), biphenyl-modified naphthol resins (polynuclear naphthol compounds in which bis-methylene group(s) connects phenolic nuclei), aminotriazine-modified phenolic resins (polynuclear phenolic compounds in which melamine, benzoguanamine, or any similar species connects phenolic nuclei), and novolac resins modified with alkoxy-containing aromatic rings (polynuclear phenolic compounds in which formaldehyde connects phenolic nuclei and alkoxy-containing aromatic rings).

Of these optional phenolic-hydroxyl-containing resins, cresol novolac resins and co-condensed novolac resins made from cresol and other phenolic compounds are particularly preferred because they give the photosensitive resin composition superior heat resistance. The cresol novolac resins and co-condensed novolac resins made from cresol and other phenolic compounds are, specifically, novolac resins made essentially from at least one cresol selected from the group consisting of o-cresol, m-cresol, and p-cresol and an aldehyde compound, optionally with other phenolic compounds.

Examples of phenolic compounds that can optionally be used include phenol; xylenols such as 2,3-xylenol, 2,4-xylenol, 2,5-xylenol, 2,6-xylenol, 3,4-xylenol, and 3,5-xylenol; ethylphenols such as o-ethylphenol, m-ethylphenol, and p-ethylphenol; butylphenols such as isopropylphenol, butylphenol, and p-t-butylphenol; alkylphenols such as p-pentylphenol, p-octylphenol, p-nonylphenol, and p-cumylphenol; halogenated phenols such as fluorophenol, chlorophenol, bromophenol, and iodophenol; monosubstituted phenols such as p-phenylphenol, aminophenol, p-nitrophenol, dinitrophenol, and trinitrophenol; fused polycyclic phenols such as 1-naphthol and 2-naphthol; and polyhydric phenols such as resorcinol, alkylresorcinols, pyrogallol, catechol, alkylcatechols, hydroquinone, alkylhydroquinones, phloroglucinol, bisphenol A, bisphenol F, bisphenol S, and dihydroxynaphthalene. Either a single phenolic compound or a combination of two or more phenolic compounds can be used. It is preferred that 0.05 to 1 mole of phenolic compound(s), if used, be used per total mole of the cresol material(s).

Examples of aldehyde compounds that can be used include formaldehyde, paraformaldehyde, trioxane, acetaldehyde, propionaldehyde, polyoxymethylene, chloral, hexamethylenetetramine, furfural, glyoxal, n-butyraldehyde, caproaldehyde, allylaldehyde, benzaldehyde, crotonaldehyde, acrolein, tetraoxymethylene, phenylacetaldehyde, o-tolualdehyde, and salicylaldehyde. Either a single aldehyde or a combination of two or more aldehydes can be used. Formaldehyde is particularly preferred because of its superior reactivity and can be used in combination with other aldehyde compounds. It is preferred that 0.05 to 1 mole of optional aldehyde compound(s), if used with formaldehyde, be used per mole of formaldehyde.

In the reaction to produce the novolac resin, the ratio of aldehyde compounds to phenolic compounds is preferably in the range of 0.3 to 1.6 moles, more preferably 0.5 to 1.3, of aldehyde compounds per mole of phenolic compounds. This leads to superior sensitivity and heat resistance of the photosensitive composition.

In an exemplary method, a phenolic compound and an aldehyde compound are allowed to react at a temperature of 60° C. to 140° C. in the presence of an acid catalyst, and then water and any residual monomers are removed under reduced pressure. Examples of acid catalysts that can be used include oxalic acid, sulfuric acid, hydrochloric acid, phenolsulfonic acid, para-toluene sulfonic acid, zinc acetate, and manganese acetate. Either a single acid catalyst or a combination of two or more catalysts can be used. Oxalic acid is particularly preferred because of its superior catalytic activity.

Of such cresol novolac resins and co-condensed novolac resins made from cresol and other phenolic compounds, particularly preferred are cresol novolac resins that incorporate meta-cresol alone and cresol novolac resins that incorporate both meta-cresol and para-cresol. In the reaction to produce the latter, the molar ratio between meta-cresol and para-cresol [meta-cresol/para-cresol] is preferably between 10/0 and 2/8, more preferably between 7/3 and 2/8. This leads to a good balance between the sensitivity and heat resistance of the photosensitive resin composition.

When an optional alkali-soluble resin is used, the proportions of the novolac phenolic resin of the invention and the optional alkali-soluble resin can be adjusted according to the intended purpose of use. It is particularly preferred that at least 60% by mass, more preferably at least 80% by mass, the novolac phenolic resin of the invention be used with respect to the total mass of the novolac phenolic resin of the invention and the optional alkali-soluble resin. This makes the advantages of the present invention, i.e., superior dry etching resistance and heat resistance and easily controllable alkali solubility, sufficiently noticeable.

The photosensitive composition according to the present invention for the formation of resist underlayer films preferably contains an organic solvent with the novolac phenolic resin of the invention and more preferably is a solution of the novolac phenolic resin of the invention in an organic solvent. Examples of organic solvents that can be used include ethylene glycol alkyl ethers such as ethylene glycol monomethyl ether, ethylene glycol monoethyl ether, ethylene glycol monopropyl ether, and ethylene glycol monobutyl ether; diethylene glycol alkyl ethers such as diethylene glycol dimethyl ether, diethylene glycol diethyl ether, diethylene glycol dipropyl ether, and diethylene glycol dibutyl ether; ethylene glycol alkyl ether acetates such as methyl cellosolve acetate and ethyl cellosolve acetate; propylene glycol alkyl ether acetates such as propylene glycol monomethyl ether acetate, propylene glycol monoethyl ether acetate, and propylene glycol monopropyl ether acetate; ketones such as acetone, methyl ethyl ketone, cyclohexanone, and methyl amyl ketone; cyclic ethers such as dioxane; and esters such as methyl 2-hydroxypropionate, ethyl 2-hydroxypropionate, ethyl 2-hydroxy-2-methylpropionate, ethyl ethoxyacetate, ethyl oxyacetate, methyl 2-hydroxy-3-methylbutanoate, 3-methoxybutyl acetate, 3-methyl-3-methoxybutyl acetate, ethyl formate, ethyl acetate, butyl acetate, methyl acetoacetate, and ethyl acetoacetate. Either one organic solvent or a combination of two or more organic solvents can be used.

The photosensitive composition according to the present invention for the formation of resist underlayer films preferably contains one or more selected from the group consisting of a photo-acid generator and a curing agent with the novolac phenolic resin of the invention. When containing a photo-acid generator, the photosensitive composition according to the present invention for the formation of resist underlayer films may contain either one photo-acid generator or two or more photo-acid generators. Likewise, when containing a curing agent, the photosensitive composition according to the present invention for the formation of resist underlayer films may contain either one curing agent or two or more curing agents.

The photo-acid generator can be, for example, an organic halide, a sulfonate, an onium salt, a diazonium salt, or a disulfone compound. Specific examples include haloalkyl-containing s-triazine derivatives such as tris(trichloromethyl)-s-triazine, tris(tribromomethyl)-s-triazine, tris(dibromomethyl)-s-triazine, and 2,4-bis(tribromomethyl)-6-p-methoxyphenyl-s-triazine;

halogen-substituted paraffin hydrocarbon compounds such as 1,2,3,4-tetrabromobutane, 1,1,2,2-tetrabromoethane, carbon tetrabromide, and iodoform; halogen-substituted cycloparaffin hydrocarbon compounds such as hexabromocyclohexane, hexachlorocyclohexane, and hexabromocyclododecane;

haloalkyl-containing benzene derivatives such as bis(trichloromethyl)benzene and bis(tribromomethyl)benzene; haloalkyl-containing sulfone compounds such as tribromomethylphenyl sulfone and trichloromethylphenyl sulfone; halogen-containing sulfolane compounds such as 2,3-dibromosulfolane; haloalkyl-containing isocyanurate compounds such as tris(2,3-dibromopropyl)isocyanurate;

sulfonium salts such as triphenylsulfonium chloride, triphenylsulfonium methanesulfonate, triphenylsulfonium trifluoromethanesulfonate, triphenylsulfonium p-toluenesulfonate, triphenylsulfonium tetrafluoroborate, triphenylsulfonium hexafluoroarsenate, and triphenylsulfonium hexafluorophosphonate;

iodonium salts such as diphenyliodonium trifluoromethanesulfonate, diphenyliodonium p-toluenesulfonate, diphenyliodonium tetrafluoroborate, diphenyliodonium hexafluoroarsenate, and diphenyliodonium hexafluorophospnate;

sulfonate compounds such as methyl p-toluenesulfonate, ethyl p-toluenesulfonate, butyl p-toluenesulfonate, phenyl p-toluenesulfonate, 1,2,3-tris(p-toluenesulfonyloxy)benzene, benzoin p-toluenesulfonate, methyl methanesulfonate, ethyl methanesulfonate, butyl methanesulfonate, 1,2,3-tris(methanesulfonyloxy)benzene, phenyl methanesulfonate, benzoin methanesulfonate, methyl trifluoromethanesulfonate, ethyl trifluoromethanesulfonate, butyl trifluoromethanesulfonate, 1,2,3-tris(trifluoromethanesulfonyloxy)benzene, phenyl trifluoromethanesulfonate, and benzoin trifluoromethanesulfonate; disulfone compounds such as diphenyl disulfone;

sulfone diazide compounds such as bis(phenylsulfonyl)diazomethane, bis(2,4-dimethylphenylsulfonyl)diazomethane, bis(cyclohexylsulfonyl)diazomethane, cyclohexylsulfonyl-(2-methoxyphenylsulfonyl)diazomethane, cyclohexylsulfonyl-(3-methoxyphenylsulfonyl)diazomethane, cyclohexylsulfonyl-(4-methoxyphenylsulfonyl)diazomethane, cyclopentylsulfonyl-(2-methoxyphenylsulfonyl)diazomethane, cyclopentylsulfonyl-(3-methoxyphenylsulfonyl)diazomethane, cyclopentylsulfonyl-(4-methoxyphenylsulfonyl)diazomethane, cyclohexylsulfonyl-(2-fluorophenylsulfonyl)diazomethane, cyclohexylsulfonyl-(3-fluorophenylsulfonyl)diazomethane, cyclohexylsulfonyl-(4-fluorophenylsulfonyl)diazomethane, cyclopentylsulfonyl-(2-fluorophenylsulfonyl)diazomethane, cyclopentylsulfonyl-(3-fluorophenylsulfonyl)diazomethane, cyclopentylsulfonyl-(4-fluorophenylsulfonyl)diazomethane, cyclohexylsulfonyl-(2-chlorophenylsulfonyl)diazomethane, cyclohexylsulfonyl-(3-chlorophenylsulfonyl)diazomethane, cyclohexylsulfonyl-(4-chlorophenylsulfonyl)diazomethane, cyclopentylsulfonyl-(2-chlorophenylsulfonyl)diazomethane, cyclopentylsulfonyl-(3-chlorophenylsulfonyl)diazomethane, cyclopentylsulfonyl-(4-chlorophenylsulfonyl)diazomethane, cyclohexylsulfonyl-(2-trifluoromethylphenylsulfonyl)diazomethane, cyclohexylsulfonyl-(3-trifluoromethylphenylsulfonyl)diazomethane, cyclohexylsulfonyl-(4-trifluoromethylphenylsulfonyl)diazomethane, cyclopentylsulfonyl-(2-trifluoromethylphenylsulfonyl)diazomethane, cyclopentylsulfonyl-(3-trifluoromethylphenylsulfonyl)diazomethane, cyclopentylsulfonyl-(4-trifluoromethylphenylsulfonyl)diazomethane, cyclohexylsulfonyl-(2-trifluoromethoxyphenylsulfonyl)diazomethane, cyclohexylsulfonyl-(3-trifluoromethoxyphenylsulfonyl)diazomethane, cyclohexylsulfonyl-(4-trifluoromethoxyphenylsulfonyl)diazomethane, cyclopentylsulfonyl-(2-trifluoromethoxyphenylsulfonyl)diazomethane, cyclopentylsulfonyl-(3-trifluoromethoxyphenylsulfonyl)diazomethane, cyclopentylsulfonyl-(4-trifluoromethoxyphenylsulfonyl)diazomethane, cyclohexylsulfonyl-(2,4,6-trimethylphenylsulfonyl)diazomethane, cyclohexylsulfonyl-(2,3,4-trimethylphenylsulfonyl)diazomethane, cyclohexylsulfonyl-(2,4,6-triethylphenylsulfonyl)diazomethane, cyclohexylsulfonyl-(2,3,4-triethylphenylsulfonyl)diazomethane, cyclopentylsulfonyl-(2,4,6-trimethylphenylsulfonyl)diazomethane, cyclopentylsulfonyl-(2,3,4-trimethylphenylsulfonyl)diazomethane, cyclopentylsulfonyl-(2,4,6-triethylphenylsulfonyl)diazomethane, cyclopentylsulfonyl-(2,3,4-triethylphenylsulfonyl)diazomethane, phenylsulfonyl-(2-methoxyphenylsulfonyl)diazomethane, phenylsulfonyl-(3-methoxyphenylsulfonyl)diazomethane, phenylsulfonyl-(4-methoxyphenylsulfonyl)diazomethane, bis(2-methoxyphenylsulfonyl)diazomethane, bis(3-methoxyphenylsulfonyl)diazomethane, bis(4-methoxyphenylsulfonyl)diazomethane, phenylsulfonyl-(2,4,6-trimethylphenylsulfonyl)diazomethane, phenylsulfonyl-(2,3,4-trimethylphenylsulfonyl)diazomethane, phenylsulfonyl-(2,4,6-triethylphenylsulfonyl)diazomethane, phenylsulfonyl-(2,3,4-triethylphenylsulfonyl)diazomethane, 2,4-dimethylphenylsulfonyl-(2,4,6-trimethylphenylsulfonyl)diazomethane, 2,4-dimethylphenylsulfonyl-(2,3,4-trimethylphenylsulfonyl)diazomethane, phenylsulfonyl-(2-fluorophenylsulfonyl)diazomethane, phenylsulfonyl-(3-fluorophenylsulfonyl)diazomethane, and phenylsulfonyl-(4-fluorophenylsulfonyl)diazomethane;

o-nitrobenzyl ester compounds such as o-nitrobenzyl-p-toluenesulfonate; and sulfone hydrazide compounds such as N,N′-di(phenylsulfonyl)hydrazide.

It is preferred that 0.1 to 20 parts by mass of photo-acid generator(s) be used per 100 parts by mass of the novolac phenolic resin of the invention. This gives the photosensitive composition high optical sensitivity.

The photosensitive composition according to the present invention for the formation of resist underlayer films may contain an organic basic compound that neutralizes the acid produced by the photo-acid generator during exposure. The organic basic compound effectively prevents variations in resist pattern size due to the movement of the acid produced by the photo-acid generator. The organic basic compound can be, for example, an organic amine compound selected from nitrogen-containing compounds. Specific examples include pyrimidine compounds such as pyrimidine, 2-aminopyrimidine, 4-aminopyrimidine, 5-aminopyrimidine, 2,4-diaminopyrimidine, 2,5-diaminopyrimidine, 4,5-diaminopyrimidine, 4,6-diaminopyrimidine, 2,4,5-triaminopyrimidine, 2,4,6-triaminopyrimidine, 4,5,6-triaminopyrimidine, 2,4,5,6-tetraaminopyrimidine, 2-hydroxypyrimidine, 4-hydroxypyrimidine, 5-hydroxypyrimidine, 2,4-dihydroxypyrimidine, 2,5-dihydroxypyrimidine, 4,5-dihydroxypyrimidine, 4,6-dihydroxypyrimidine, 2,4,5-trihydroxypyrimidine, 2,4,6-trihydroxypyrimidine, 4,5,6-trihydroxypyrimidine, 2,4,5,6-tetrahydroxypyrimidine, 2-amino-4-hydroxypyrimidine, 2-amino-5-hydroxypyrimidine, 2-amino-4,5-dihydroxypyrimidine, 2-amino-4,6-dihydroxypyrimidine, 4-amino-2,5-dihydroxypyrimidine, 4-amino-2, 6-dihydroxypyrimidine, 2-amino-4-methylpyrimidine, 2-amino-5-methylpyrimidine, 2-amino-4,5-dimethylpyrimidine, 2-amino-4,6-dimethylpyrimidine, 4-amino-2,5-dimethylpyrimidine, 4-amino-2,6-dimethylpyrimidine, 2-amino-4-methoxypyrimidine, 2-amino-5-methoxypyrimidine, 2-amino-4,5-dimethoxypyrimidine, 2-amino-4,6-dimethoxypyrimidine, 4-amino-2,5-dimethoxypyrimidine, 4-amino-2,6-dimethoxypyrimidine, 2-hydroxy-4-methylpyrimidine, 2-hydroxy-5-methylpyrimidine, 2-hydroxy-4,5-dimethylpyrimidine, 2-hydroxy-4,6-dimethylpyrimidine, 4-hydroxy-2,5-dimethylpyrimidine, 4-hydroxy-2,6-dimethylpyrimidine, 2-hydroxy-4-methoxypyrimidine, 2-hydroxy-4-methoxypyrimidine, 2-hydroxy-5-methoxypyrimidine, 2-hydroxy-4,5-dimethoxypyrimidine, 2-hydroxy-4,6-dimethoxypyrimidine, 4-hydroxy-2,5-dimethoxypyrimidine, and 4-hydroxy-2,6-dimethoxypyrimidine;

pyridine compounds such as pyridine, 4-dimethylaminopyridine, and 2,6-dimethylpyridine;

amine compounds substituted with hydroxyalkyls having 1 to 4 carbon atoms, such as diethanolamine, triethanolamine, tr isopropanolamine, tris(hydroxymethyl)aminomethane, and bis(2-hydroxyethyl)iminotris(hydroxymethyl)methane; and

aminophenol compounds such as 2-aminophenol, 3-aminophenol, and 4-aminophenol. Either a single organic basic compound or a combination of two or more organic basic compounds can be used. Pyrimidine compounds, pyridine compounds, and hydroxy-bearing amine compounds are particularly preferred because the use of any of these compounds leads to superior consistency in the size of exposed resist patterns. In particular, hydroxy-bearing amine compounds are preferred.

It is preferred that 0.1% to 100% by mole, more preferably 1% to 50% by mole, organic basic compound(s), if added, be added with respect to the photo-acid generator content.

Examples of curing agents that may be contained in the photosensitive composition according to the present invention for the formation of resist underlayer films include melamine, guanamine, glycoluril, and urea compounds substituted with at least one group selected from methylol, alkoxymethyl, and acyloxymethyl, resol resins, epoxy compounds, isocyanate compounds, azide compounds, compounds with alkenyl-ether or similar double bonds, acid anhydrides, and oxazoline compounds.

The melamine compounds include, for example, hexamethylolmelamine, hexamethoxymethylmelamine, hexamethylolmelamine compounds with 1 to 6 methylol groups methoxymethylated, hexamethoxyethylmelamine, hexaacyloxymethylmelamines, and hexamethylolmelamine compounds with 1 to 6 methylol groups acyloxymethylated.

The guanamine compounds include, for example, tetramethylolguanamine, tetramethoxymethylguanamine, tetramethoxymethylbenzoguanamine, tetramethylolguanamine compounds with 1 to 4 methylol groups methoxymethylated, tetramethoxyethylguanamine, tetraacyloxyguanamines, and tetramethylolguanamine compounds with 1 to 4 methylol groups acyloxymathylated.

The glycoluril compounds include, for example, 1,3,4,6-tetrakis(methoxymethyl)glycoluril, 1,3,4,6-tetrakis(butoxymethyl)glycoluril, and 1,3,4,6-tetrakis(hydroxymethyl)glycoluril.

The urea compounds include, for example, 1,3-bis(hydroxymethyl)urea, 1,1,3,3-tetrakis(butoxymethyl)urea, and 1,1,3,3-tetrakis(methoxymethyl)urea.

The resol resins include, for example, polymers resulting from an alkali-catalyzed reaction between a phenolic-hydroxyl-containing compound, e.g., phenol, an alkyl phenol such as cresol or xylenol, phenylphenol, resorcinol, biphenyl, a bisphenol such as bisphenol A or bisphenol F, naphthol, or dihydroxynaphthalene, and an aldehyde compound.

The epoxy compounds include, for example, tris(2,3-epoxypropyl)isocyanurate, trimethylolmethane triglycidyl ether, trimethylolpropane triglycidyl ether, and triethylolethane triglycidyl ether.

The isocyanate compounds include, for example, tolylene diisocyanate, diphenylmethane diisocyanate, hexamethylene diisocyanate, and cyclohexane diisocyanate.

The azide compounds include, for example, 1,1′-biphenyl-4,4′-bisazide, 4,4′-methylidenebisazide, and 4,4′-oxybisazide.

The compounds with alkenyl-ether or similar double bonds include, for example, ethylene glycol divinyl ether, trimethylene glycol divinyl ether, 1,2-propanediol divinyl ether, 1,4-butanediol divinyl ether, tetramethylene glycol divinyl ether, neopentylglycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylolpropane trivinyl ether.

The acid anhydrides include, for example, aromatic acid anhydrides such as phthalic anhydride, trimellitic anhydride, pyromellitic anhydride, 3,3′,4,4′-benzophenonetetracarboxylic dianhydride, biphenyltetracarboxylic dianhydride, 4,4′-(isopropylidene)diphthalic anhydride, and 4,4′-(hexafluoroisopropylidene)diphthalic anhydride; and alicyclic carboxylic anhydrides such as tetrahydrophthalic anhydride, methyltetrahydrophthalic anhydride, hexahydrophthalic anhydride, methylhexahydrophthalic anhydride, endomethylenetetrahydrophthalic anhydride dodecenylsuccinic anhydride, and trialkyltetrahydrophthalic anhydrides.

Of these, glycoluril compounds, urea compounds, and resol resins are particularly preferred. With these highly effective curing agents, resist underlayer films formed from the composition will be more resistant to dry etching and thermal decomposition than with the others. In particular, glycoluril compounds are preferred.

It is preferred that 0.1 to 50 parts by mass, more preferably 0.1 to 30 parts by mass, even more preferably 0.5 to 20 parts by mass, of curing agent(s), if contained in the photosensitive composition according to the present invention for the formation of resist underlayer films, be mixed per 100 parts by mass of the novolac phenolic resin of the invention.

The photosensitive composition according to the present invention for the formation of resist underlayer films may further contain a photosensitizer for ordinary resist materials. The photosensitizer can be, for example, a quinonediazide-bearing compound. Specific examples of quinonediazide-bearing compounds include complete esters, partial esters, amides, and partial amides of aromatic (poly)hydroxy compounds with quinonediazide-bearing sulfonic acids, such as naphthoquinone-1,2-diazide-5-sulfonic acid, naphthoquinone-1,2-diazide-4-sulfonic acid, and ortho-anthraquinone diazide sulfonic acid.

Examples of aromatic (poly)hydroxy compounds that can be used include polyhydroxybenzopheone compounds such as 2,3,4-trihydroxybenzophenone, 2,4,4′-trihydroxybenzophenone, 2,4,6-trihydroxybenzophenone, 2,3,6-trihydroxybenzophenone, 2,3,4-trihydroxy-2′-methylbenzophenone, 2,3,4,4′-tetrahydroxybenzophenone, 2,2′,4,4′-tetrahydroxybenzophenone, 2,3′,4,4′,6-pentahydroxybenzophenone, 2,2′,3,4,4′-pentahydroxybenzophenone, 2,2′,3,4,5-pentahydroxybenzophenone, 2,3′,4,4′,5′,6-hexahydroxybenzophenone, and 2,3,3′,4,4′,5′-hexahydroxybenzophenone;

bis[(poly)hydroxyphenyl]alkane compounds such as bis(2,4-dihydroxyphenyl)methane, bis(2,3,4-trihydroxyphenyl)methane, 2-(4-hydroxyphenyl)-2-(4′-hydroxyphenyl)propane, 2-(2,4-dihydroxyphenyl)-2-(2′,4′-dihydroxyphenyl)propane, 2-(2,3,4-trihydroxyphenyl)-2-(2′,3′,4′-trihydroxyphenyl)propane, 4,4′-(1-[4-{2-(4-hydroxyphenyl)-2-propyl}phenyl]ethylidene)bisphenol, and 3,3′-dimethyl(1-[4-{2-(3-methyl-4-hydroxyphenyl)-2-propyl}phenyl]ethylidene)bisphenol;

tris(hydroxyphenyl)methane compounds such as tris(4-hydroxyphenyl)methane, bis(4-hydroxy-3,5-dimethylphenyl)-4-hydroxyphenylmethane, bis(4-hydroxy-2,5-dimethylphenyl)-4-hydroxyphenylmethane, bis(4-hydroxy-3,5-dimethylphenyl)-2-hydroxyphenylmethane, bis(4-hydroxy-2,5-dimethylphenyl)-2-hydroxyphenylmethane, bis(4-hydroxy-2,5-dimethylphenyl)-3,4-dihydroxyphenylmethane, and bis(4-hydroxy-3,5-dimethylphenyl)-3,4-dihydroxyphenylmethane and their methyl substituted derivatives; and

bis(cyclohexylhydroxyphenyl)(hydroxyphenyl)methane compounds such as bis(3-cyclohexyl-4-hydroxyphenyl)-3-hydroxyphenylmethane, bis(3-cyclohexyl-4-hydroxyphenyl)-2-hydroxyphenylmethane, bis(3-cyclohexyl-4-hydroxyphenyl)-4-hydroxyphenylmethane, bis(5-cyclohexyl-4-hydroxy-2-methylphenyl)-2-hydroxyphenylmethane, bis(5-cyclohexyl-4-hydroxy-2-methylphenyl)-3-hydroxyphenylmethane, bis(5-cyclohexyl-4-hydroxy-2-methylphenyl)-4-hydroxyphenylmethane, bis(3-cyclohexyl-2-hydroxyphenyl)-3-hydroxyphenylmethane, bis(5-cyclohexyl-4-hydroxy-3-methylphenyl)-4-hydroxyphenylmethane, bis(5-cyclohexyl-4-hydroxy-3-methylphenyl)-3-hydroxyphenylmethane, bis(5-cyclohexyl-4-hydroxy-3-methylphenyl)-2-hydroxyphenylmethane, bis(3-cyclohexyl-2-hydroxyphenyl)-4-hydroxyphenylmethane, bis(3-cyclohexyl-2-hydroxyphenyl)-2-hydroxyphenylmethane, bis(5-cyclohexyl-2-hydroxy-4-methylphenyl)-2-hydroxyphenylmethane, and bis(5-cyclohexyl-2-hydroxy-4-methylphenyl)-4-hydroxyphenylmethane and their methyl-substituted derivatives. Either a single photosensitizer or a combination of two or more photosensitizers can be used.

It is preferred that 5 to 50 parts by mass of photosensitizer(s), if used, be mixed per 100 parts by mass of solid resin in the photosensitive composition according to the present invention for the formation of resist underlayer films. This gives the composition superior optical sensitivity.

The photosensitive composition according to the present invention for the formation of resist underlayer films may contain a surfactant for purposes such as improved film production properties, better adhesion of the pattern, and reduced occurrence of development defects. Examples of surfactants that can be used include nonionic surfactants, e.g., polyoxyethylene alkyl ether compounds such as polyoxyethylene lauryl ether, polyoxyethylene stearyl ether, polyoxyethylene cetyl ether, and polyoxyethylene oleyl ether, polyoxyethylene alkylallyl ethers such as polyoxyethylene octylphenol ether and polyoxyethylene nonylphenol ether, polyoxyethylene-polyoxypropylene block copolymers, sorbitan fatty acid ester compounds such as sorbitan monolaurate, sorbitan monopalmitate, sorbitan monostearate, sorbitan monooleate, sorbitan trioleate, and sorbitan tristearate, and polyoxyethylene sorbitan fatty acid ester compounds such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorosurfactants, i.e., surfactants that have fluorine atoms in their molecular structure, such as copolymers of fluoroaliphatic-bearing polymerizable monomers with [poly(oxyalkylene)] (meth)acrylate; and silicone surfactants, i.e., surfactants that have a silicone structural portion in their molecular structure. Either a single surfactant or a combination of two or more surfactants can be used.

It is preferred that 0.001 to 2 parts by mass of surfactant(s) be mixed per 100 parts by mass of solid resin in the photosensitive composition according to the present invention for the formation of resist underlayer films.

The photosensitive composition according to the present invention for the formation of resist underlayer films may further contain filler. The filler improves the hardness and heat resistance of the coatings. The photosensitive composition according to the present invention for the formation of resist underlayer films preferably contains inorganic filler, although organic fillers are acceptable. Examples of inorganic fillers that can be used include silica, mica, talc, clay, bentonite, montmorillonite, kaolinite, wollastonite, calcium carbonate, calcium hydroxide, magnesium carbonate, titanium oxide, alumina, aluminum hydroxide, barium sulfate, barium titanate, potassium titanate, zinc oxide, and fiberglass. Silica is particularly preferred because it reduces the thermal expansion coefficient of the composition.

The photosensitive composition according to the present invention for the formation of resist underlayer films is preferably one that optionally contains, besides the novolac phenolic resin of the invention, additives dissolved or dispersed in an organic solvent, such as other resins, photo-acid generators, curing agents, photosensitizers, surfactants, fillers, curing agents, organic basic compounds, dyes, pigments, curing agents, and dissolution aids. Applying a solution, for example, in an organic solvent to a substrate or any similar thing produces a coating. With regard to dyes, pigments, and dissolution aids, the manufacturer can select appropriate one(s) from those commonly used as additives for resist materials considering factors such as the purpose of use.

The photosensitive composition according to the present invention for the formation of resist underlayer films can be conditioned by combining its components, described above, and mixing them using, for example, a mixer. If the photosensitive composition for the formation of resist underlayer films contains fillers and/or pigments, it can be conditioned through dispersion or mixing using a dispersing machine, such as a dissolver, a homogenizer, or a three-roll mill.

The photosensitive composition according to the present invention for the formation of resist underlayer films can also be used as a resist material. A solution or dispersion of the photosensitive composition according to the present invention for the formation of resist underlayer films in an organic solution can be directly used as a resist solution, and a dried film of the solution or dispersion in an organic solvent can be used as a resist film. The support film for the resist film can be a polyethylene, polypropylene, polycarbonate, polyethylene terephthalate, or other synthetic resin film. Either a single-layer film or multiple multilayer films can be used. The support film may have a surface treated by corona discharge or coated with a release agent.

A resist underlayer film according to the present invention is a cured form of a photosensitive composition according to the present invention for the formation of resist underlayer films. The substrate on which the resist underlayer film is formed (the substrate to be worked) can be, for example, a silicon wafer or an aluminum-coated wafer. The resist underlayer film according to the present invention can be formed by, for example, applying the photosensitive composition according to the present invention for the formation of resist underlayer films to a surface such as that of the substrate to be worked or that of an additional underlayer film, described hereinafter, and curing the resulting coating by heating with or without ultraviolet irradiation. Techniques such as spin coating, roll coating, and dipping can be used to apply the photosensitive composition according to the present invention for the formation of resist underlayer films. The heating temperature is usually between 50° C. and 450° C., preferably between 150° C. and 300° C. The heating time is usually between 5 to 600 seconds.

The substrate to be worked may be coated beforehand with an additional underlayer film formed using a composition according to the present invention for the formation of resist underlayer films but different from the resist underlayer film (hereinafter also referred to as “an additional underlayer film”). Examples of additional underlayer films include organic anti-reflective coatings disclosed in publications such as Japanese Examined Patent Application Publication No. 6-12452 and Japanese Unexamined Patent Application Publication No. 59-93448.

The resist underlayer film according to the present invention usually has a thickness of 10 to 1,000 nm, preferably 10 nm to 500 nm.

The photosensitive composition according to the present invention for the formation of resist underlayer films can also be used as a resist material for the formation of a resist pattern. In an exemplary photolithographic process that uses such a resist material, the resist material is applied to a resist underlayer film formed on the substrate to be worked, and then prebaked at a temperature of 60° C. to 150° C. Any coating technique can be used, such as spin coating, roll coating, flow coating, dip coating, spray coating, and doctor blading. A resist pattern is then created. When the resist material is of the positive type, the desired resist pattern is exposed to light through a predetermined mask, and an alkali developer is applied to dissolve the exposed parts, forming the resist pattern.

Examples of light sources that can be used include infrared light, visible light, ultraviolet light, far-ultraviolet light, X-rays, and electron beam. The ultraviolet light can be, for example, the g-line (wavelength, 436 nm), h-line (wavelength, 405 nm), or i-line (wavelength, 365 nm) from a high-pressure mercury vapor lamp, a KrF excimer laser (wavelength, 248 nm), an ArF excimer laser (wavelength, 193 nm), an F2 excimer laser (wavelength, 157 nm), or an EUV laser (wavelength, 13.5 nm). Whatever the light source is, the resulting resist pattern is formed with high resolution by virtue of the high optical sensitivity and alkali developability of the photosensitive composition according to the present invention for the formation of resist underlayer films.

Furthermore, coatings obtained using a photosensitive composition according to the present invention for the formation of resist underlayer films are suitable for use as permanent coatings, coatings that remain in finished products, because of the superior heat resistance and dry etching resistance of the composition. Products having spaces between their components may warp due to the thermal expansion of permanent coatings varying between the component and space sides. Permanent coatings made from a photosensitive composition according to the present invention for the formation of resist underlayer films are highly advantageous in that they rarely cause such warping.

A permanent coating is a coating of a photosensitive composition formed on a component or interposed between components of a product, primarily a semiconductor device such as an IC or an LSI device or a display such as a thin display, and left in the product even after the product is completed. Specific examples of permanent coatings related to semiconductor devices include solder resists, packaging material, underfill, package bonding layers for circuit devices or other components, and layers for bonding integrated circuit devices to a circuit board. Specific examples of permanent coatings related to thin displays, typified by LCDs and OELDs, include protective coatings for thin-film transistors, protective coatings for liquid-crystal color filters, black matrix, and spacers.

### EXAMPLES

The following describes the present invention in further detail by providing examples and other information. However, the present invention is not limited to the examples and information provided. The “parts” and “%” mentioned hereinafter are by mass unless otherwise specified.

### <GPC of Resins>

GPC was used to measure the molecular weight distributions of resins. Polystyrenes were used as standards, and the measurement conditions were as follows.

### (GPC Conditions)

Instrument: Tosoh Corporation “HLC-8220 GPC”

Columns: Showa Denko K.K. “Shodex KF802” (8.0 mm I.D.×300 mm)+Showa Denko K.K. “Shodex KF802” (8.0 mm I.D.×300 mm)+Showa Denko K.K. “Shodex KF803” (8.0 mm I.D.×300 mm)+Showa Denko K.K. “Shodex KF804” (8.0 mm I.D.×300 mm)

Detector: RI (a differential refractometer)

Column temperature: 40° C.
Developing solvent Tetrahydrofuran (THF)
Flow rate 1.0 mL/min

Sample: A solution of 1.0% by mass resin, on a solid basis, in tetrahydrofuran filtered through a microfilter (5 μL)

Data processing: Tosoh Corporation “GPC-8020 Model II Data Analysis Version 4.30”

Standard samples: As directed in the measurement manual for “GPC-8020 Model II Data Analysis Version 4.30,” the below listed monodisperse polystyrenes, with known molecular weights, were used.

### (Monodisperse Polystyrenes)

Tosoh Corporation “A-500”

Tosoh Corporation “A-1000”

Tosoh Corporation “A-2500”

Tosoh Corporation “A-5000”

Tosoh Corporation “F-1”

Tosoh Corporation “F-2”

Tosoh Corporation “F-4”

Tosoh Corporation “F-10”

Tosoh Corporation “F-20”

Tosoh Corporation “F-40”

Tosoh Corporation “F-80”

Tosoh Corporation “F-128”

Tosoh Corporation “F-288”

Tosoh Corporation “F-550”

### <¹³C-NMR Spectroscopy of Resins>

The resins were structurally characterized through the measurement of their ¹³C-NMR spectrum. JEOL Ltd. “JNM-LA300” was used to analyze DMSO-d₆ solutions as samples. The ¹³C-NMR spectroscopy conditions were as follows.

### (¹³C-NMR Spectroscopy Conditions)

Measurement mode: SGNNE (NOE suppression with complete 1H decoupling)

Pulse angle: 45° C. pulses

Sample concentration: 30 wt %

Number of scans: 10000

### Synthesis Example 1

### <Synthesis of a Phenolic Trinuclear Compound>

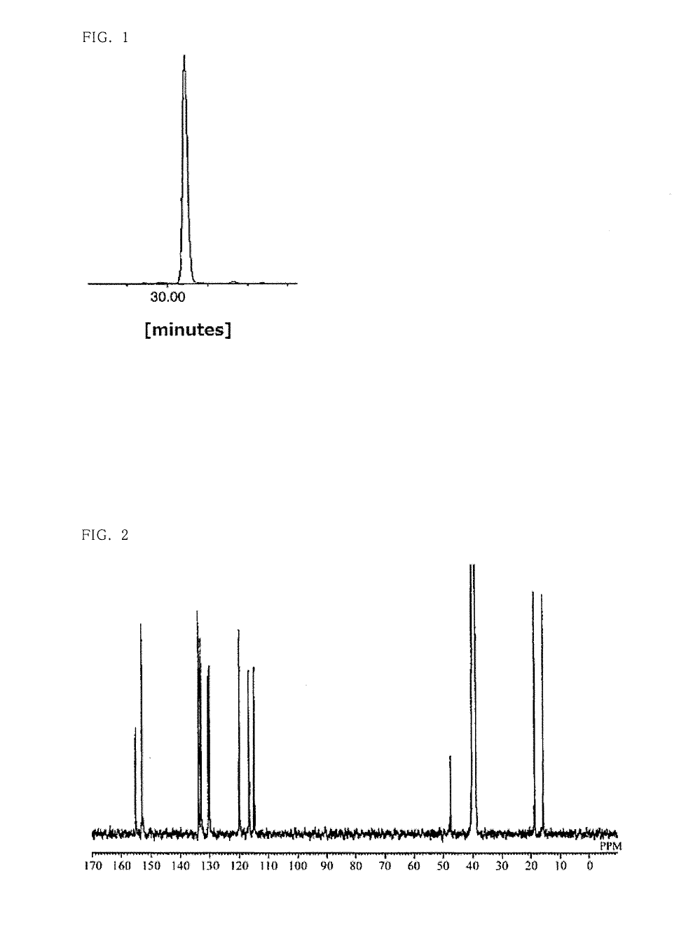

A 2-L four-neck flask fitted with a condenser was charged with 293.2 g (2.4 moles) of 2,5-xylenol, 122 g (1 mole) of 4-hydroxybenzaldehyde, and 500 mL of 2-ethoxyethanol, and the 2,5-xylenol and 4-hydroxybenzaldehyde were dissolved in the 2-ethoxyethanol. To the reaction solution in the four-neck flask was added 10 mL of sulfuric acid with cooling in an ice bath. The resulting mixture was heated at 100° C. for 2 hours using a mantle heater, reacting with stirring. After the reaction had completed, water was added to the reaction solution to induce reprecipitation. The resulting crude product was dissolved again, in acetone this time, and water was added to induce reprecipitation. The product obtained through the reprecipitation was collected by filtration and dried in a vacuum, yielding 213 g of a white crystalline precursor compound (phenolic trinuclear compound (1)). Phenolic trinuclear compound (1), when identified by GPC and ¹³C-NMR spectroscopy, was the desired compound, and its purity as determined from a GPC area ratio was 98.2% by mass. FIGS. 1 and 2 are GPC and ¹³C-NMR spectral charts, respectively, of phenolic trinuclear compound (1).

### Synthesis Example 2

### <Synthesis of a Phenolic Trinuclear Compound>

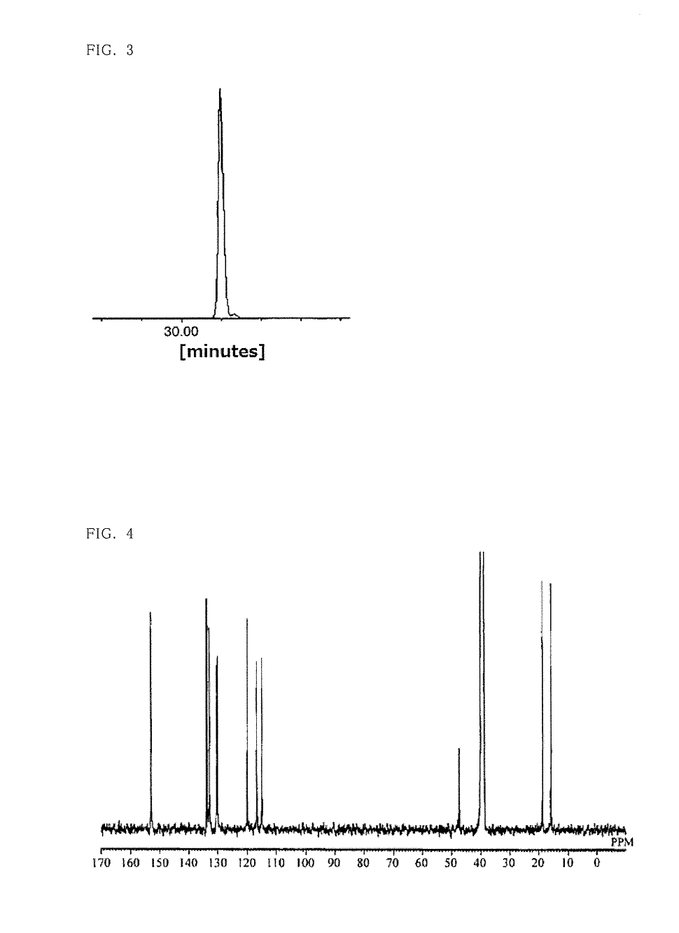

The procedure of Synthesis Example 1 was repeated using 106.1 g (1 mole) of benzaldehyde instead of the 122 g (1 mole) of 4-hydroxybenzaldehyde, yielding 206 g of a white crystalline precursor compound (phenolic trinuclear compound (2)). Phenolic trinuclear compound (2), when identified by GPC and ¹³C-NMR spectroscopy, was the desired compound, and its purity as determined from a GPC area ratio was 98.7% by mass. FIGS. 3 and 4 are GPC and ¹³C-NMR spectral charts, respectively, of phenolic trinuclear compound (2).

### Synthesis Example 3

### <Synthesis of a Novolac Phenolic Resin>

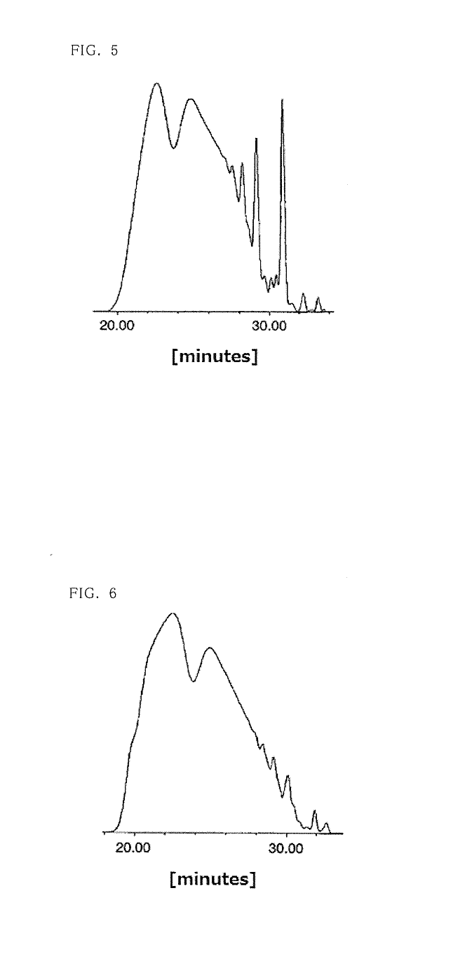

A 300-mL four-neck flask fitted with a condenser was charged with 17.4 g (0.05 moles) of phenolic trinuclear compound (1), obtained in Synthesis Example 1, 1.6 g (0.05 moles) of 92% paraformaldehyde, 15 mL of 2-ethoxyethanol, and 15 mL of acetic acid, and the phenolic trinuclear compound (1) and paraformaldehyde were dissolved in a solvent mixture of 2-ethoxyethanol and acetic acid (phenolic trinuclear compound (1):phenolic trinuclear compound (2)=100:0). To the reaction solution in the four-neck flask was added 10 mL of sulfuric acid with cooling in an ice bath. The resulting mixture was heated at 80° C. for 4 hours in an oil bath, reacting with stirring. After the reaction had completed, water was added to the reaction solution to induce reprecipitation. The resulting crude product was dissolved again, in acetone this time, and water was added to induce reprecipitation. The product obtained through the reprecipitation was collected by filtration and dried in a vacuum, yielding 16.8 g of a light-red powdery novolac phenolic resin (novolac resin (3-a)). FIG. 5 is a GPC chart of novolac resin (3-a). Novolac resin (3-a) was characterized by GPC, with the result that the number-average molecular weight (Mn)=2,733, the weight-average molecular weight (Mw)=10,984, and the polydispersity (Mw/Mn)=4.019.

### Synthesis Example 4

### <Synthesis of a Novolac Phenolic Resin>

The procedure of Synthesis Example 3 was repeated using 4.2 g (0.012 moles) of phenolic trinuclear compound (1), obtained in Synthesis Example 1, and 12.6 g (0.038 moles) of phenolic trinuclear compound (2), obtained in Synthesis Example 2, instead of the 17.4 g (0.05 moles) of phenolic trinuclear compound (1), obtained in Synthesis Example 1 (phenolic trinuclear compound (1):phenolic trinuclear compound (2)=25:75), yielding 16.5 g of a light-red powdery novolac phenolic resin (novolac resin (3-b)). FIG. 6 is a GPC chart of novolac resin (3-b). Novolac resin (3-b) was characterized by GPC, with the result that the number-average molecular weight (Mn)=3,654, the weight-average molecular weight (Mw)=18,798, and the polydispersity (Mw/Mn)=5.144.

### Synthesis Example 5

### <Synthesis of a Novolac Phenolic Resin>

The procedure of Synthesis Example 3 was repeated using 8.7 g (0.025 moles) of phenolic trinuclear compound (1), obtained in Synthesis Example 1, and 8.3 g (0.025 moles) of phenolic trinuclear compound (2), obtained in Synthesis Example 2, instead of the 17.4 g (0.05 moles) of phenolic trinuclear compound (1), obtained in Synthesis Example 1 (phenolic trinuclear compound (1):phenolic trinuclear compound (2)=50:50), yielding 16.2 g of a light-red powdery novolac phenolic resin (novolac resin (3-c)). FIG. 7 is a GPC chart of novolac resin (3-c). Novolac resin (3-c) was characterized by GPC, with the result that the number-average molecular weight (Mn)=2,529, the weight-average molecular weight (Mw)=11,421, and the polydispersity (Mw/Mn)=4.516.

### Synthesis Example 6

### <Synthesis of a Novolac Phenolic Resin>

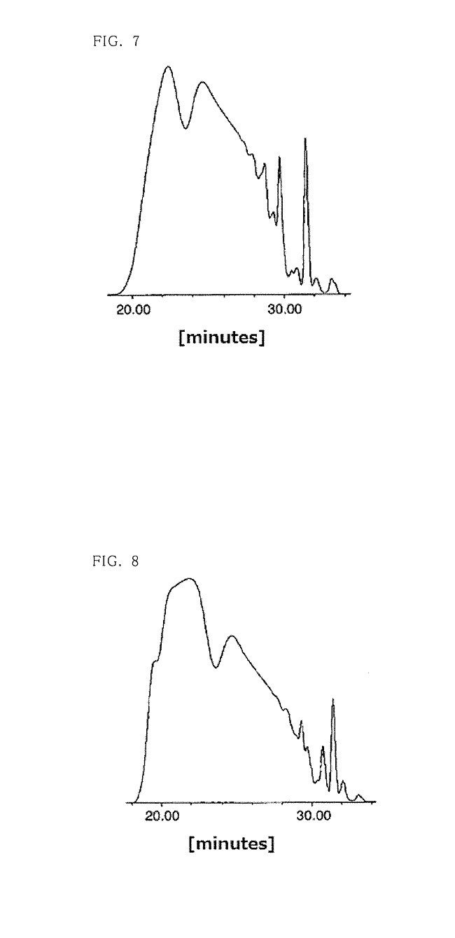

The procedure of Synthesis Example 3 was repeated using 13.2 g (0.038 moles) of phenolic trinuclear compound (1), obtained in Synthesis Example 1, and 4.0 g (0.012 moles) of phenolic trinuclear compound (2), obtained in Synthesis Example 2, instead of the 17.4 g (0.05 moles) of phenolic trinuclear compound (1), obtained in Synthesis Example 1 (phenolic trinuclear compound (1):phenolic trinuclear compound (2)=75:25), yielding 16.2 g of a light-red powdery novolac phenolic resin (novolac resin (3-d)). FIG. 8 is a GPC chart of novolac resin (3-d). Novolac resin (3-d) was characterized by GPC, with the result that the number-average molecular weight (Mn)=3,313, the weight-average molecular weight (Mw)=25,435, and the polydispersity (Mw/Mn)=7.678.

### Comparative Synthesis Example 1

### <Synthesis of a Fluorene-Bisphenol Novolac>

A reactor equipped with a condenser, a thermometer, and a stirring device was charged with 100 g of 9,9-bis(4-hydroxyphenyl)fluorine, 100 g of propylene glycol monomethyl ether (PGMEA), and 50 g of paraformaldehyde. The mixture was heated to 120° C. with 2 g of oxalic acid while water was removed, reacting for 5 hours, yielding 98 g of a novolac phenolic resin having a structural unit of the formula below (novolac resin (3-e)).

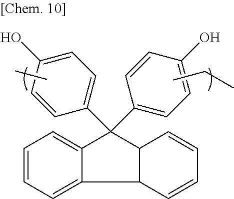

### Examples 1 to 4 and Comparative Example 1

Each of novolac resins (3-a) to (3-e), synthesized in Synthesis Examples 3 to 6 and Comparative Synthesis Example 1, was mixed with a curing agent (1,3,4,6-tetrakis(methoxymethyl)glycoluril, Tokyo Chemical Industry Co., Ltd.) and PGMEA into a solution in proportions of 10/0.5/50 (parts by mass) as summarized in Table 1. The solutions were filtered through 0.2-μm membrane filters, giving photosensitive compositions according to the present invention for the formation of resist underlayer films and a comparative photosensitive composition for the formation of resist underlayer films. Coatings (resist underlayer films) made using these compositions were tested for alkali solubility, heat resistance, and dry etching resistance as follows. The test results are summarized in Table 1.

### <Alkali Solubility Testing>

The evaluation of alkali solubility was based on the measurement of the alkali dissolution rate of the coatings. The detailed procedure was as follows. The photosensitive composition for the formation of resist underlayer films, according to the present invention or for comparative purposes, was applied to a 5-inch silicon wafer using a spin coating. The applied composition was dried on a hot plate at 110° C. for 60 seconds, giving a silicon wafer with an approximately 1-μm-thick coating (resist underlayer film) thereon. After 60 seconds of immersion in an alkali developer (a 2.38% aqueous solution of tetramethylammonium hydroxide), the wafer was dried on a hot plate at 110° C. for 60 seconds. The thickness of the coating of the photosensitive composition for the formation of resist underlayer films or that for comparative purposes was measured before and after the immersion in the developer. The difference divided by 60 (ADR (nm/s) was the alkali solubility test result. The coating thickness measurement was through the use of a film thickness measurement instrument (Filmetrics, Inc. “f-20”).

### <Heat Resistance Testing>

The evaluation of heat resistance was based on the thermal decomposition temperature of the coatings. The detailed procedure was as follows. The photosensitive composition for the formation of resist underlayer films, according to the present invention or for comparative purposes, was applied to a 5-inch silicon wafer using a spin coater. The applied composition was dried on a hot plate at 110° C. for 60 seconds, giving a silicon wafer with an approximately 1-μm-thick coating (resist underlayer film) thereon. Some resin was scraped off of the wafer, and its thermal decomposition temperature was measured. The determination of the thermal decomposition temperature was through the use of a thermogravimetry/differential thermal analyzer (Seiko Instruments Inc.; trade name, TG/DTA 6200), with which the resin was heated at a constant rate and its weight loss was monitored in a nitrogen atmosphere. The parameters were: temperature range, room temperature to 400° C.; heating temperature, 10° C./min.

### <Dry Etching Resistance Testing>

The photosensitive composition for the formation of resist underlayer films, according to the present invention or for comparative purposes, was applied to a 5-inch silicon wafer using a spin coater. The applied composition was dried at 180° C. for 60 seconds and subsequently at 350° C. for 120 seconds in a hot plate with an oxygen concentration of 20% by volume, giving a silicon wafer with a 0.3-μm-thick coating (resist underlayer film) thereon. The resulting wafer was etched using an etching unit (Shinko Seiki K.K. “EXAM”) under CF₄/Ar/O₂ conditions (CF₄, 40 mL/min; Ar, 20 mL/min; O₂, 5 mL/min; pressure, 20 Pa; RF power, 200 W; processing time, 40 seconds; temperature, 15° C.). The thickness of the coating of the photosensitive composition for the formation of resist underlayer films or that for comparative purposes was measured before and after the etching. Dry etching resistance was graded on the basis of the calculated etching rate (nm/min), as “ ” if the etching rate was 150 nm/min or less and “x” if the etching rate exceeded 150 nm/min.

TABLE 1

| | | | | | Comparative |
|---|---|---|---|---|---|
| | Example 1 | Example 2 | Example 3 | Example 4 | Example 1 |
| Novolac resin (3-a) | 10 | — | — | — | — |
| Novolac resin (3-b) | — | 10 | — | — | — |
| Novolac resin (3-c) | — | — | 10 | — | — |
| Novolac resin (3-d) | — | — | — | 10 | — |
| Novolac resin (3-e) | — | — | — | — | 10 |
| Curing agent | 0.5 | 0.5 | 0.5 | 0.5 | 0.5 |
| PGMEA | 50 | 50 | 50 | 50 | 50 |
| Total | 60.5 | 60.5 | 60.5 | 60.5 | 60.5 |

Tests

| | | | | | |
|---|---|---|---|---|---|
| Thermal decomposition | 332 | 320 | 313 | 326 | 173 |
| temperature (° C.) | | | | | |
| ADR (nm/sec) | >200 | 60 | 120 | 150 | 32 |
| Dry etching resistance | ◯ | ◯ | ◯ | ◯ | X |

The coatings of the photosensitive compositions for the formation of resist underlayer films containing novolac resins (3-a) to (3-d) (Examples 1 to 4), which were novolac phenolic resins of the invention, had a thermal decomposition temperature of higher than 310° C., exhibiting superior heat resistance. These coatings were highly resistant to dry etching as well. The order of alkali dissolution rate (ADR), from slower to faster, was Example 2 (novolac resin (3-b)), Example 3 (novolac resin (3-c)), Example 4 (novolac resin (3-d)), and then Example 1 (novolac resin (3-a)), indicating that alkali solubility increased with increasing proportion of the phenolic trinuclear compound (1) to the total amount of the raw material phenolic trinuclear compounds. That is, it is possible to control alkali solubility by adjusting the ratio between phenolic trinuclear compounds (1) and phenolic trinuclear compounds (2). Comparative Example 1 was inferior to Examples 1 to 4 in all of thermal decomposition temperature, ADR, and dry etching resistance.

1-11. (canceled)

12. A curable resin composition comprising a novolac phenolic resin and a curing agent, the novolac phenolic resin resulting from an acid-catalyzed reaction between one or more phenolic trinuclear compounds (A) and an aldehyde (B), the one or more phenolic trinuclear compounds selected from the group consisting of compounds of general formula (1), 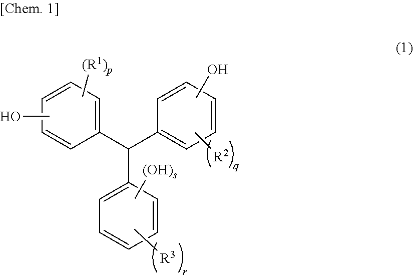
[in formula (1), R¹, R², and R³ each independently represent a substituted or unsubstituted alkyl having 1 to 8 carbon atoms; if there are a plurality of R¹ groups, the R¹ groups may be of the same or different kinds; if there are a plurality of R² groups, the R² groups may be of the same or different kinds; if there are a plurality of R³ groups, the R³ groups may be of the same or different kinds; p and q are each independently an integer of 1 to 4; r is an integer of 0 to 4; and s is 1 or 2, with the proviso that a sum of r and s is 5 or less], and
compounds of general formula (2), 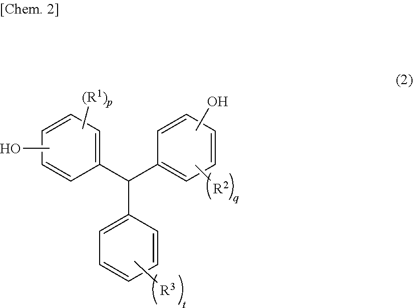
[in formula (2), R¹, R², R³, p, and q have the same meanings as in formula (1), and t is an integer of 0 to 5].

13. The curable resin composition according to claim 12, wherein the one or more phenolic trinuclear compounds (A) are selected from the group consisting of compounds of general formula (1-1), (1-2), (1-7), (1-8), (1-13), (1-14), (2-1), or (2-2), 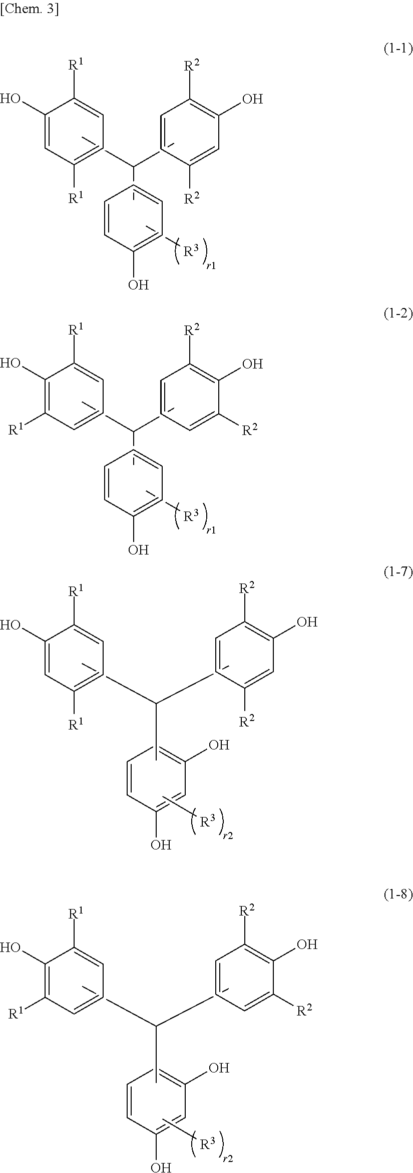 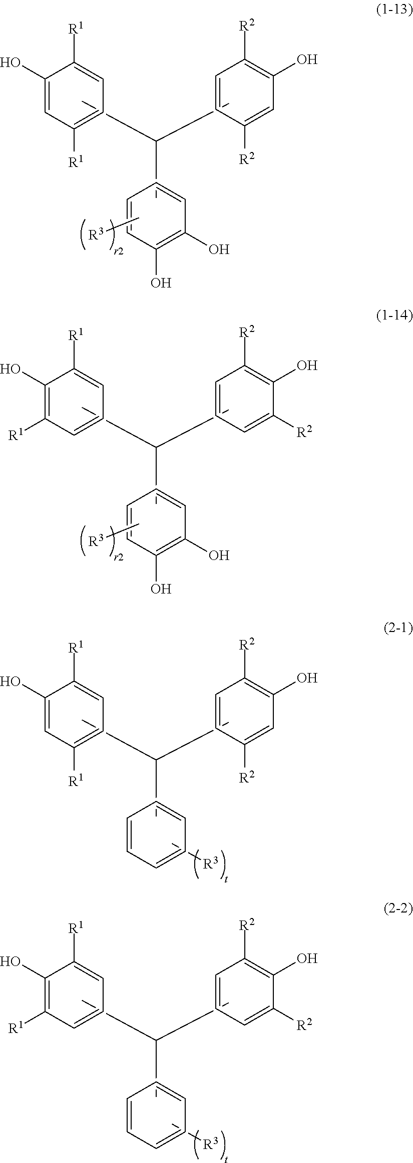
[in these formulae, R¹, R², and R³ each independently represent substituted or unsubstituted alkyl having 1 to 8 carbon atoms; the plurality of R¹ groups may be of the same or different kinds; the plurality of R² groups may be of the same or different kinds; if there are a plurality of R³ groups, the R³ groups may be of the same or different kinds; r1 is an integer of 0 to 4; r2 is an integer of 0 to 3; and t is an integer of 0 to 5].

14. The curable resin composition according to claim 12, wherein the novolac phenolic resin has one or more structural portions, as a repeat unit or units, selected from the group consisting of structural units (I-1) of general formula (I-1), 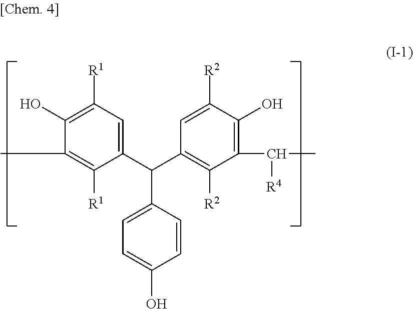
[in formula (I-1), R¹ and R² have the same meanings as in formula (1), and R⁴ represents hydrogen, substituted or unsubstituted alkyl, or substituted or unsubstituted aryl],
structural units (I-2) of general formula (I-2), 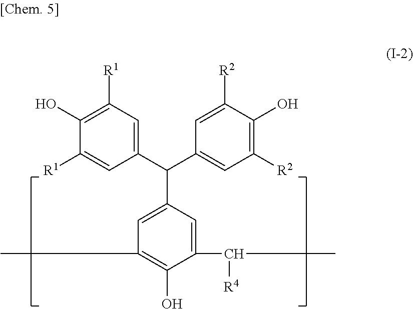
[in formula (I-2), R¹ and R² have the same meanings as in formula (1), and R⁴ has the same meaning as in formula (I-1)],
structural units (II-1) of general formula (II-1), 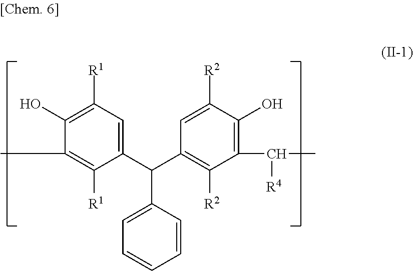
[in formula (II-1), R¹ and R² have the same meanings as in formula (1), and R⁴ has the same meaning as in formula (I-1)], and
structural units (II-2) of general formula (II-2), 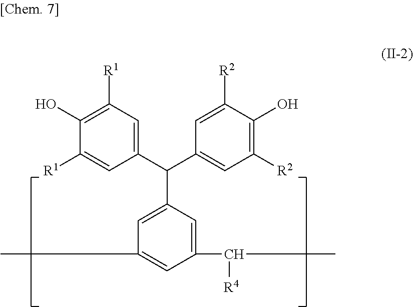
[in formula (II-2), R¹ and R² have the same meanings as in formula (1), and R⁴ has the same meaning as in formula (I-1)].

15. The curable resin composition according to claim 12, wherein R¹ and R² are both methyl.

16. The curable resin composition according to claim 12, wherein the aldehyde (B) is formaldehyde.

17. The curable resin composition according to claim 12, wherein the curable resin composition is a composition for forming a resist underlayer film.

18. The curable resin composition according to claim 13, wherein the curable resin composition is a composition for forming a resist underlayer film.

19. The curable resin composition according to claim 14, wherein the curable resin composition is a composition for forming a resist underlayer film.

20. The curable resin composition according to claim 15, wherein the curable resin composition is a composition for forming a resist underlayer film.

21. The curable resin composition according to claim 16, wherein the curable resin composition is a composition for forming a resist underlayer film.

22. A resist underlayer film comprising a cured form of the composition according to claim 17 for forming a resist underlayer film.
